(19) United States
(12) Patent Application Publication
(10) Pub. No.: US 2024/0408516 A1
(43) Pub. Date: Dec. 12, 2024

(54) PARTICLE SEPARATING APPARATUS AND METHOD OF SEPARATING PARTICLES USING THE SAME

(71) Applicants: Samsung Display Co., LTD., Yongin-si, Gyeonggi-do (KR); INDUSTRY FOUNDATION OF CHONNAM NATIONAL UNIVERSITY, Gwangju (KR)

(72) Inventors: Jong Ho SHIN, Yongin-si (KR); Jinsoo PARK, Gwangju (KR); Ki Cheol SONG, Yongin-si (KR); Hyun Woo JEON, Gwangju (KR)

(73) Assignees: Samsung Display Co., LTD., Yongin-si, Gyeonggi-do (KR); INDUSTRY FOUNDATION OF CHONNAM NATIONAL UNIVERSITY, Gwangju (KR)

(21) Appl. No.: 18/582,943

(22) Filed: Feb. 21, 2024

(30) Foreign Application Priority Data
Jun. 7, 2023 (KR) 10-2023-0073184
Sep. 14, 2023 (KR) 10-2023-0122604

(51) Int. Cl. B01D 21/26; B01D 21/24; B01D 21/28; B04C 3/00; B04C 3/06

(52) U.S. Cl. CPC B01D 21/265; B01D 21/2416; B01D 21/283; B04C 3/06; B01D 2221/14; B04C 2003/006

(57) ABSTRACT

A particle separating apparatus and a method of separating particles using the same are provided. The particle separating apparatus comprises a base part, a micro channel disposed in the base part, an inlet portion disposed at an end portion of the micro channel, wherein light-emitting elements, Newtonian fluid and viscoelastic fluid are injected into the inlet portion, an inlet flow path connecting the inlet portion and the micro channel, an outlet portion disposed at an opposite end portion of the micro channel, wherein the light-emitting elements, the Newtonian fluid and the viscoelastic fluid are discharged from the outlet portion, an outlet flow path connecting the micro channel and the outlet portion, and a vortex generator disposed under the inlet portion to generate a surface acoustic wave.

### CROSS REFERENCE TO RELATED APPLICATION(S)

This application claims priority from Korean Patent Application Nos. 10-2023-0073184, filed on Jun. 7, 2023, and 10-2023-0122604, filed on Sep. 14, 2023, in the Korean Intellectual Property Office, the entire contents of which are incorporated herein by reference.

### BACKGROUND

### 1. Technical Field

Embodiments relate to a particle separating apparatus and a method of separating particles using the particle separating apparatus.

### 2. Description of the Related Art

Display devices become more important as multimedia technology evolves. Accordingly, a variety of types of display devices such as organic light-emitting display (OLED) devices and liquid-crystal display (LCD) devices are currently used.

Display devices include a display panel such as an organic light-emitting display panel and a liquid-crystal display panel for displaying images. Among them, the organic light-emitting display panel may include light-emitting elements. For example, light-emitting diodes (LEDs) may include an organic light-emitting diode (OLED) including an organic material as a luminescent material, and an inorganic light-emitting diode including an inorganic material as a luminescent material.

Among inorganic light-emitting diodes included in display devices, light-emitting elements may be dispersed on a wafer and formed on a substrate of a display device. In case that the particle sizes of the light-emitting elements are non-uniform or different, defects may occur in display devices. Therefore, ongoing efforts are being made to ensure the uniformity of the particle size of light-emitting elements.

### SUMMARY

Embodiments provide a particle separating apparatus that separates particles having different sizes.

Embodiments also provide a method of fabricating a display device capable of reducing defects thereof by selecting light-emitting elements having a uniform size.

However, embodiments of the disclosure are not limited to those set forth herein. The above and other embodiments will become more apparent to one of ordinary skill in the art to which the disclosure pertains by referencing the detailed description of the disclosure given below.

According to an aspect of the disclosure, a particle separating apparatus may include a base part, a micro channel disposed in the base part, an inlet portion disposed at an end portion of the micro channel, wherein light-emitting elements, Newtonian fluid and viscoelastic fluid may be injected into the inlet portion, an inlet flow path connecting the inlet portion and the micro channel, an outlet portion disposed at an opposite end portion of the micro channel, wherein the light-emitting elements, the Newtonian fluid and the viscoelastic fluid may be discharged from the outlet portion, an outlet flow path connecting the micro channel and the outlet portion, and a vortex generator disposed under the inlet portion may generate a surface acoustic wave.

In an embodiment, the vortex generator may include a piezoelectric substrate, and first and second element electrodes disposed on the piezoelectric substrate and arranged alternately with each other in plan view.

In an embodiment, an electrical signal applied to the first element electrode and the second element electrode may be an alternating current (AC) electrical signal.

In an embodiment, a frequency used for the surface acoustic wave may be in a range of about 10 MHz to about 300 MHz.

In an embodiment, the micro channel may have a ratio of height to width in a range of about 2 to about 3.

In an embodiment, a width of the micro channel may be in a range of about 20 μm to about 30 μm.

In an embodiment, a length of the micro channel may be in a range of about 15 mm to about 25 mm.

In an embodiment, the inlet portion may include a first inlet through which the Newtonian fluid in which the light-emitting elements are dispersed is injected, and a second inlet through which the viscoelastic fluid is injected, and wherein the vortex generator may be disposed under the first inlet.

In an embodiment, a ratio of a flow rate of the Newtonian fluid to a flow rate of the viscoelastic fluid may be in a range of about 3 to about 7.

In an embodiment, the flow rate of the Newtonian fluid may be in a range of about 20 μl/min to about 30 μl/min.

In an embodiment, the inlet flow path may include a first inlet path and a second inlet path connected to the first inlet, wherein the light-emitting elements and the Newtonian fluid may move through the first inlet path and the second inlet path, and a third inlet path connected to the second inlet path, wherein the viscoelastic fluid may move through the third inlet path, and wherein the first inlet path and the second inlet path may surround the third inlet path.

In an embodiment, a diameter of each of the first inlet path and the second inlet path may be in a range of about 20 μm to about 40 μm.

In an embodiment, the outlet portion may include a first outlet and a second outlet, wherein small light-emitting elements among the light-emitting elements and the Newtonian fluid may be discharged from the first and second outlets, and a third outlet, wherein large light-emitting elements among the light-emitting elements and the viscoelastic fluid may be discharged from the third outlet, and wherein the first outlet, the second outlet and the third outlet may be spaced apart from one another.

In an embodiment, the outlet flow path may include a first outlet path connecting the micro channel and the first outlet, a second outlet path connecting the micro channel and the second outlet, and a third outlet path connecting the micro channel and the third outlet, and wherein the first outlet path, the second outlet path and the third outlet path may be branched off from the opposite end portion of the micro channel.

In an embodiment, an angle between the micro channel and the first outlet may be in a range of about 150 degrees to about 165 degrees.

According to an aspect of the disclosure, a method of separating light-emitting elements having different sizes, the method may include providing a particle separating apparatus including: a micro channel disposed in a base part; an inlet portion disposed at an end portion of the micro channel and including a first inlet through which light-emitting elements and Newtonian fluid are injected and a second inlet through which viscoelastic fluid is injected; an inlet flow path connecting the inlet portion and the micro channel; an outlet portion disposed at an opposite end portion of the micro channel, wherein the light-emitting elements, the Newtonian fluid and the viscoelastic fluid may be discharged from the outlet portion; an outlet flow path connecting the micro channel and the outlet portion; and a vortex generator disposed under the inlet portion; injecting the Newtonian fluid in which the light-emitting elements are dispersed into the micro channel through the first inlet, and injecting the viscoelastic fluid into the micro channel through the second inlet, generating a surface acoustic wave in the vortex generator to propagate the surface acoustic wave to the first inlet, separating normal light-emitting elements from abnormal light-emitting elements in the micro channel, and discharging the normal light-emitting elements and the Newtonian fluid to the outlet portion through the outlet flow path, and the abnormal light-emitting elements and the viscoelastic fluid separated from the normal light-emitting elements in the micro channel to the outlet portion through the outlet flow path.

In an embodiment, the surface acoustic wave may generate acoustic streaming that drives a flow of the Newtonian fluid moving in the first inlet, and wherein a vortex may be generated in the Newtonian fluid by the acoustic streaming to disperse the light-emitting elements.

In an embodiment, the outlet flow path may include a first outlet path, a second outlet path and a third outlet path branched off from the micro channel, and wherein the outlet portion may include a first outlet connected to the first outlet path, a second outlet connected to the second outlet path, and a third outlet connected to the third outlet path.

In an embodiment, the normal light-emitting elements separated in the micro channel and the Newtonian fluid may be discharged to the first outlet through the first outlet path and the second outlet through the second outlet path, and wherein the abnormal light-emitting elements and the viscoelastic fluid may be discharged to the third outlet through the third outlet path.

In an embodiment, the abnormal light-emitting elements among the light-emitting elements may be larger in size than the normal light-emitting elements.

According to an embodiment, a particle separating apparatus may separate abnormal light-emitting elements from normal light-emitting elements using Newtonian fluid and viscoelastic fluid. For example, the particle separating apparatus may eliminate settlement and aggregation of light-emitting elements by way of disposing a vortex generator in the inlet portion.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment.

FIG. 2 is a schematic plan view showing arrangement of a plurality of lines included in a display device according to an embodiment.

FIG. 3 is a schematic diagram of an equivalent circuit of a sub-pixel according to an embodiment.

FIG. 4 is a schematic plan view showing a pixel of a display device according to an embodiment.

FIG. 5 is a schematic cross-sectional view taken along line E1-E1′ of FIG. 4.

FIG. 6 is a schematic cross-sectional view taken along line E2-E2′ of FIG. 4.

FIG. 7 is a schematic view showing a light-emitting element according to an embodiment.

FIG. 8 is a schematic perspective view showing a particle separating apparatus according to an embodiment.

FIG. 9 is a schematic perspective view showing the structure of the particle separating apparatus of FIG. 8 excluding the body.

FIG. 10 is a schematic plan view showing the particle separating apparatus of FIG. 9.

FIG. 11 is a schematic cross-sectional view showing a micro channel of the particle separating apparatus of FIG. 9.

FIG. 12 is a schematic perspective view showing a vortex generator of the particle separating apparatus of FIG. 9.

FIG. 13 is a schematic view showing the first inlet in case that the vortex generator of the particle separating apparatus of FIG. 9 is not in operation.

FIG. 14 is a schematic view showing the first inlet in case that the vortex generator of the particle separating apparatus of FIG. 9 is in operation.

FIG. 15 is a schematic plan view showing a micro channel of a particle separating apparatus according to an embodiment.

FIG. 16 is a schematic plan view showing area A of FIG. 15.

FIG. 17 is a schematic plan view showing area B of FIG. 15.

FIG. 18 is a schematic plan view showing area C of FIG. 15.

FIG. 19 is a schematic block diagram illustrating a large particle separating apparatus according to an embodiment.

FIG. 20 is an image of the inlet portion of the particle separating apparatus according to Embodiment 1 in case that the vortex generator is not operated.

FIG. 21 is an image of the inlet portion of the particle separating apparatus according to Embodiment 1 in case that the vortex generator is operated.

FIG. 22 is an image of the outlet flow path of the particle separating apparatus according to Embodiment 1.

FIG. 23 is an image of the outlet flow path of the particle separating apparatus according to Embodiment 2.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

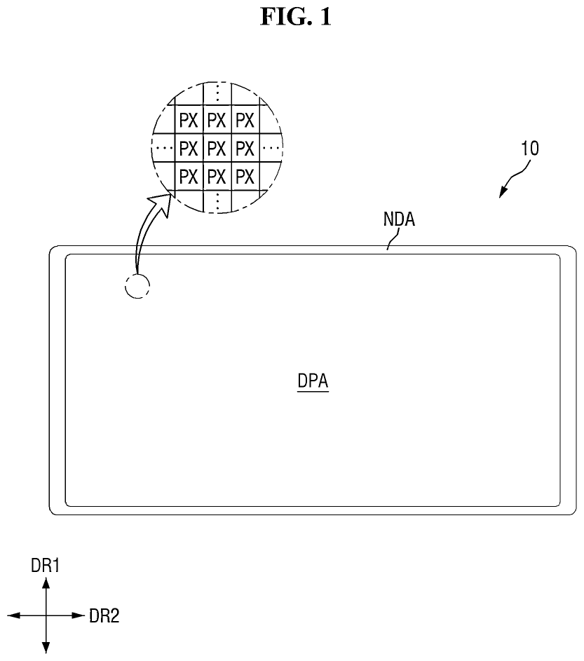

FIG. 1 is a schematic plan view of a display device according to an embodiment.

Referring to FIG. 1, the display device 10 may display a moving image or a still image. A display device 10 may refer to any electronic device that provides a display screen. For example, the display device 10 may include a television set, a laptop computer, a monitor, an electronic billboard, the Internet of Things (IoT) devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device 10 may include a display panel for providing a display screen. For example, the display panel may include an inorganic light-emitting diode display panel, an organic light-emitting display panel, a quantum-dot light-emitting display panel, a plasma display panel, a field emission display panel, etc. In the following description, an inorganic light-emitting diode display panel may be implemented as an example of the display device 10, but embodiments are not limited thereto. Any other display panel may be implemented as long as the technical idea of the disclosure may be equally applied.

The shape of the display device 10 may be modified in a variety of ways. For example, the display device 10 may have shapes such as a rectangle with longer lateral sides, a rectangle with longer vertical sides, a square, a quadrangle with rounded corners (e.g., vertices), other polygons, a circle, etc. The shape of a display area DPA of the display device 10 may also be similar to the overall shape of the display device 10. In the example shown in FIG. 1, the display device 10 may have a rectangular shape with the longer sides in a second direction DR2.

The display device 10 may include a display area DPA and a non-display area NDA. In the display area DPA, images may be displayed. In the non-display area NDA, images may not be displayed. The display area DPA may be referred to as an active area, and the non-display area NDA may also be referred to as an inactive area. The display area DPA may generally occupy the center portion of the display device 10.

The display area DPA may include pixels PX. The pixels PX may be arranged in a matrix. The shape of each pixel PX may be a rectangle or a square when viewed from the top (or in plan view), but embodiments are not limited thereto. Each pixel may have a diamond shape having sides inclined with respect to a direction. The pixels PX may be arranged in stripes or in a pattern of islands. Each of the pixels PX may include one or more light-emitting elements each emitting light of a certain wavelength band to represent a color.

The non-display area NDA may be disposed around the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 10. Lines or circuit drivers included in the display device 10 may be disposed in each of the non-display area NDA, or external devices may be mounted in each of the non-display area NDA.

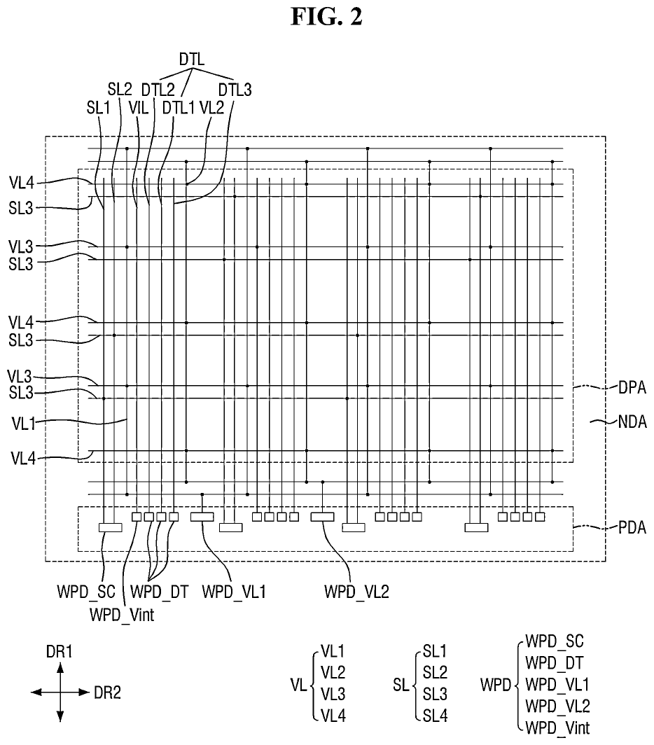

FIG. 2 is a schematic plan view showing arrangement of a plurality of lines included in a display device according to an embodiment.

Referring to FIG. 2, the display device 10 may include a plurality of lines. The display device 10 may include scan lines SL (e.g., SL1, SL2, and SL3), data lines DTL (e.g., DTL1, DTL2, and DTL3), an initialization voltage line VIL, and voltage lines VL (e.g., VL1, VL2, VL3, and VL4). For example, other lines may be further disposed in the display device 10.

The first scan line SL1 and the second scan line SL2 may extend in the first direction DR1. The first scan line SL1 and the second scan line SL2 may be disposed adjacent to each other, and may be spaced apart from other first and second scan lines SL1 and SL2 in the second direction DR2. The first scan line SL1 and the second scan line SL2 may be connected to a scan wire pad WPD_SC connected to a scan driver. The first scan line SL1 and the second scan line SL2 may extend from a pad area PDA positioned in the non-display area NDA to the display area DPA.

The third scan line SL3 may extend in the second direction DR2, and may be spaced apart from another third scan line SL3 in the first direction DR1. One third scan line SL3 may be connected to one or more first scan lines SL1 or one or more second scan lines SL2. According to an embodiment, the first scan line SL1 and the second scan line SL2 may be formed as a conductive layer that is disposed on a different layer from the third scan line SL3. The scan lines SL may have a mesh structure on the entire surface of the display area DPA, but embodiments are not limited thereto.

As used herein, when an element is referred to as being “connected” or “coupled” to another element, it may be directly connected or coupled to the element or intervening elements may be present. For example, such elements may be understood as a single integrated element with one portion thereof connected to another portion. Moreover, when an element is referred to as being “connected” to another element, it may be in direct contact with the element and also electrically connected to the element.

The data lines DTL may extend in the first direction DR1. The data lines DTL may include a first data line DTL1, a second data line DTL2 and a third data line DTL3. The first, second, and third data lines DTL1, DTL2, and DTL3 may be disposed adjacent to one another as a group. The data lines DTL1, DTL2, and DTL3 may extend from the pad area PDA positioned in the non-display area NDA to the display area DPA. However, embodiments are not limited thereto. The data lines DTL may be substantially equally spaced apart from one another and may be disposed between a first voltage line VL1 and a second voltage line VL2 to be described later.

The initialization voltage line VIL may extend in the first direction DR1. The initialization voltage line VIL may be disposed between the data lines DTL and the first and second scan lines SL1 and SL2. The initialization voltage line VIL may extend from the pad area PDA positioned in the non-display area NDA to the display area DPA.

The first voltage line VL1 and the second voltage line VL2 may extend in the first direction DR1, and the third voltage line VL3 and the fourth voltage line VL4 may extend in the second direction DR2. The first voltage line VL1 and the second voltage line VL2 may be arranged alternately in the second direction DR2, and the third voltage line VL3 and the fourth voltage line VL4 may be arranged alternately in the first direction DR1. The first voltage lines VL1 and the second voltage lines VL2 may extend in the first direction DR1 and may traverse the display area DPA. Some of the third voltage line VL3 and the fourth voltage lines VL4 may be disposed in the display area DPA, and the others may be disposed in the non-display area NDA positioned on the sides (e.g., opposite sides) of the display area DPA in the first direction DR1. The first voltage lines VL1 and the second voltage lines VL2 may be formed as a conductive layer, which is different from the third voltage lines VL3 and the fourth voltage lines VL4. For example, the first and second voltage lines VL1 and VL2 may be formed on a layer, and the third and fourth voltage lines VL3 and VL4 may be formed on another layer. The first voltage line VL1 may be connected to at least one third voltage line VL3, and the second voltage line VL2 may be connected to at least one fourth voltage line VL4, such that the voltage lines VL may have a mesh structure in the entirely display area DPA. However, embodiments are not limited thereto.

The first scan lines SL1, the second scan lines SL2, the data lines DTL, the initialization voltage line VIL, the first voltage lines VL1 and the second voltage lines VL2 may be electrically connected to one or more wire pads WPD. The wire pads WPD may be disposed in the non-display areas NDA. According to the embodiment, the wire pads WPD may be disposed in the pad area PDA positioned on the lower side of the display area DPA that is opposite to the upper side of the display area DPA in the first direction DR1. The first and second scan lines SL1 and SL2 may be connected to the scan wire pad WPD_SC disposed in the pad area PDA, and the data lines DTL may be connected to different data wire pads WPD_DT, respectively. The initialization voltage line VIL may be connected to the initialization wiring pad WPD_Vint, the first voltage line VL1 may be connected to a first voltage wire pad WPD_VL1, and the second voltage line VL2 may be connected to the second voltage wire pad WPD_VL2. External devices may be mounted on the wire pads WPD. External devices may be mounted on the wire pads WPD by an anisotropic conductive film, ultrasonic bonding, etc. Although the wire pads WPD are disposed in the pad area PDA positioned on the lower side of the display area DPA in the drawings, embodiments are not limited thereto. In another example, some of the wire pads WPD may be disposed on the upper side or on one of the left and right sides of the display area DPA.

Each of the pixels PX or sub-pixels SPXn of the display device 10 may include a pixel driving circuit, where n is an integer of 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to an embodiment, each of the sub-pixels SPXn of the display device 10 may have a 3T-1C structure, i.e., a pixel driving circuit may include three transistors and one capacitor. In the following description, the pixel driving circuit having the 3T1C structure will be described as an example. However, embodiments are not limited thereto. A variety of modified structure may be implemented such as a 2T-1C structure, a 7T-1C structure and a 6T-1C structure.

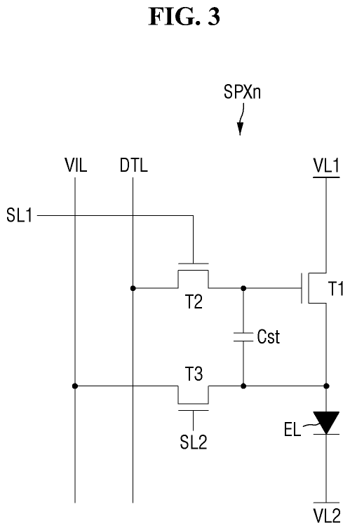

FIG. 3 is a schematic diagram of an equivalent circuit of a sub-pixel according to an embodiment.

Referring to FIG. 3, each of the sub-pixels SPXn of the display device 10 according to an embodiment may include three transistors T1, T2, and T3 and one storage capacitor Cst in addition to a light-emitting diode EL.

The light-emitting diode EL may emit light in proportion to the current supplied through the first transistor T1. The light-emitting diode EL may include a first electrode, a second electrode, and at least one light-emitting element disposed therebetween. The light-emitting element may emit light in a certain wavelength range by an electric signal transferred from the first electrode and the second electrode.

A first end portion of the light-emitting diode EL may be connected to a source electrode of the first transistor T1, and a second end portion thereof may be connected to a second voltage line VL2 from which a low-level voltage (hereinafter referred to as a second supply voltage) lower than a high-level voltage (hereinafter referred to as a first supply voltage) of a first voltage line VL1 is applied.

The first transistor T1 may adjust or control a current flowing from the first voltage line VL1 from which the first supply voltage is supplied to the light-emitting diode EL according to the voltage difference between a gate electrode and the source electrode of the first transistor T1. For example, the first transistor T1 may be a driving transistor for driving the light-emitting diode EL. The gate electrode of the first transistor T1 may be connected to a source electrode of the second transistor T2, the source electrode of the first transistor T1 may be connected to the first electrode of the light-emitting diode EL, and the drain electrode of the first transistor T1 may be connected to the first voltage line VL1 from which the first supply voltage is applied.

The second transistor T2 may be turned on by a scan signal of the first scan line SL1 to connect the data line DTL and the gate electrode of the first transistor T1. The gate electrode of the second transistor T2 may be connected to the first scan line SL1, the source electrode of the second transistor T2 may be connected to the gate electrode of the first transistor T1, and the drain electrode of the second transistor T2 may be connected to the data line DTL.

A third transistor T3 may be turned on by a scan signal of a second scan line SL2 to connect the initialization voltage line VIL and the first end portion of the light-emitting diode EL. The gate electrode of the third transistor T3 may be connected to the second scan line SL2, the drain electrode of the third transistor T3 may be connected to the initialization voltage line VIL, and the source electrode of the third transistor T3 may be connected to an end portion of the light-emitting diode EL or the source electrode of the first transistor T1.

The source electrode and the drain electrode of each of the transistors T1, T2, and T3 are not limited to those described above. In another example, the transistors T1, T2, and T3 may be connected in the different way. For example, each of the transistors T1, T2, and T3 may be formed as a thin-film transistor. For example, although each of the transistors T1, T2, and T3 implemented as an n-type MOSFET (e.g., metal oxide semiconductor field effect transistor) in the example shown in FIG. 3, embodiments are not limited thereto. For example, each of the transistors T1, T2, and T3 may be implemented as a p-type MOSFET, or some of the transistors T1, T2, and T3 may be implemented as n-type MOSFETs, and the others may be implemented as p-type MOSFETs.

The storage capacitor Cst may be formed between the gate electrode and the source electrode of the first transistor T1. The storage capacitor Cst may store a voltage difference between the gate voltage and the source voltage of the first transistor T1.

Hereinafter, the structure of one pixel PX of the display device 10 according to an embodiment will be described in detail with reference to other drawings.

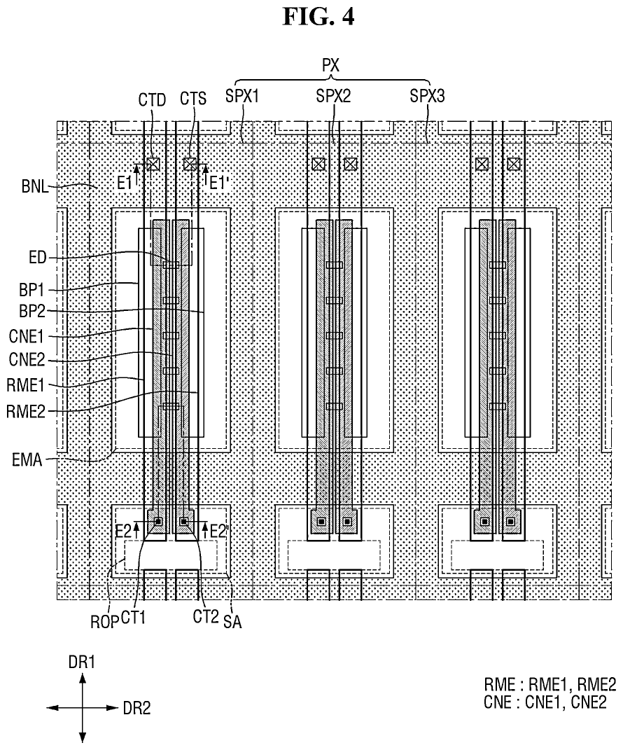

FIG. 4 is a schematic plan view showing a pixel of a display device according to an embodiment. FIG. 4 shows a layout of electrodes RME (e.g., RME1 and RME2), bank pattern layers BP1 and BP2, a bank layer BNL, light-emitting elements ED, and connection electrodes CNE (e.g., CNE1 and CNE2) disposed in a pixel PX of a display device 10 when viewed from the top (or in plan view).

Referring to FIG. 4, each of the pixels PX of the display device 10 may include sub-pixels SPXn. For example, a pixel PX may include a first sub-pixel SPX1, a second sub-pixel SPX2 and a third sub-pixel SPX3. The first sub-pixel SPX1 may emit light of a first color, the second sub-pixel SPX2 may emit light of a second color, and the third sub-pixel SPX3 may emit light of a third color. For example, the first color may be blue, the second color may be green, and the third color may be red. However, embodiments are not limited thereto. All the sub-pixels SPXn may emit light of the same color. According to an embodiment, the sub-pixels SPXn may emit blue light. Although the single pixel PX includes three sub-pixels SPXn in the example shown in the drawings, embodiments are not limited thereto. The pixel PX may include more than three sub-pixels SPXn.

Each of the sub-pixels SPXn of the display device 10 may include an emission area EMA and a non-emission area. In the emission area EMA, light-emitting elements ED may be disposed to emit light of a certain wavelength band. In the non-emission area, the light-emitting elements ED may not be disposed, and the lights emitted from the light-emitting elements ED may not reach, and thus any light does not emit therefrom.

The emission area EMA may include an area in which the light-emitting elements ED are disposed, and may include an area adjacent to the light-emitting elements ED where lights emitted from the light-emitting elements ED exit. For example, the emission area EMA may also include an area in which lights emitted from the light-emitting elements ED are reflected or refracted by other elements to exit. The light-emitting elements ED may be disposed in each of the sub-pixels SPXn, and the emission area may include the area where the light-emitting elements ED are disposed and the adjacent area.

Although the emission areas EMA of the sub-pixels SPXn have the uniform area in the example shown in the drawings, embodiments are not limited thereto. In some embodiments, the emission areas EMA of the sub-pixels SPXn may have different areas according to a color or wavelength band of light emitted from the light-emitting elements ED disposed in the respective sub-pixels.

Each of the sub-pixels SPXn may further include a subsidiary area SA disposed in the non-emission area. The subsidiary area SA of each sub-pixel SPXn may be disposed on the lower side of the emission area EMA that is opposite to the upper side of the emission area EMA in the first direction DR1. The emission areas EMA and the subsidiary areas SA may be arranged alternately in the first direction DR1, and each subsidiary area SA may be disposed between the emission areas EMA of different sub-pixels SPXn spaced apart from each other in the first direction DR1. For example, the emission areas EMA and the subsidiary areas SA may be alternately arranged in the first direction DR1, and the emission areas EMA and the subsidiary areas SA may be repeatedly arranged in the second direction DR2. However, embodiments are not limited thereto. The emission areas EMA and the subsidiary areas SA of the pixels PX may have an arrangement different from that of FIG. 4.

Any light-emitting element ED may not be disposed in the subsidiary areas SA and thus any light is not emitted therefrom. The electrodes RME disposed in the sub-pixels SPXn may be partially disposed in the subsidiary areas SA. The electrodes RME disposed in different sub-pixels SPXn may be disposed separately from one another at separation regions ROP of the subsidiary areas SA.

The lines and circuit elements of the circuit layer disposed in each pixel PX and connected to the light-emitting elements ED may be connected to the first, second, and third sub-pixels SPX1, SPX2, and SPX3. For example, the lines and circuit elements may not be disposed in the area occupied by each sub-pixel SPXn or the emission area EMA but may be disposed regardless of the position of the emission area EMA in a pixel (or single pixel) PX.

The bank layer BNL may be disposed to surround the sub-pixels SPXn, the emission area EMA and the subsidiary area SA. The bank layer BNL may be disposed at the boundary area between the sub-pixels SPXn adjacent to each other in the first direction DR1 and the second direction DR2, and may also be disposed at the boundary area between the emission area EMA and the subsidiary area SA. The sub-pixels SPXn, the emission areas EMA and the subsidiary areas SA of the display device 10 may be distinguished from one another by the bank layer BNL. The distance between the sub-pixels SPXn, the emission areas EMA and the subsidiary areas SA may vary according to the width of the bank layer BNL.

The bank layer BNL may be disposed in a lattice pattern on the front surface of the display area DPA including portions extending in the first direction DR1 and the second direction DR2 when viewed from the top (or in plan view). The bank layer BNL may be disposed along the border area of each of the sub-pixels SPXn to distinguish between adjacent sub-pixels SPXn. For example, the bank layer BNL may be disposed to surround the emission area EMA and the subsidiary area SA disposed in each of the sub-pixels SPXn to distinguish between them.

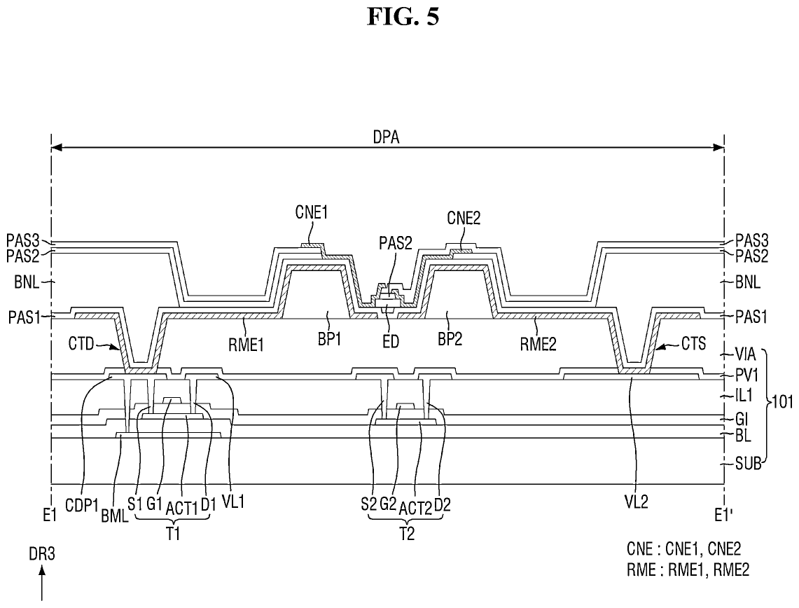

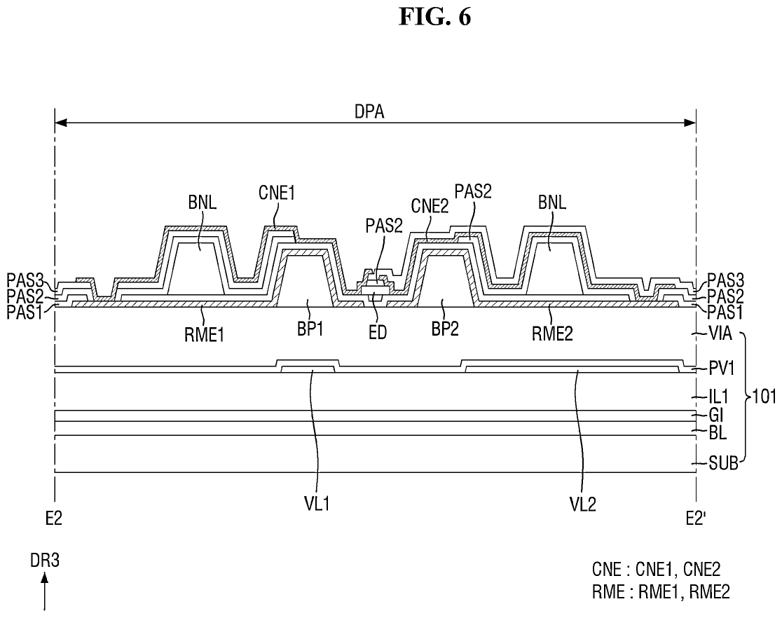

FIG. 5 is a cross-sectional view taken along line E1-E1′ of FIG. 4. FIG. 6 is a schematic cross-sectional view taken along line E2-E2′ of FIG. 4. FIG. 5 shows a cross section passing through the end portions (e.g., opposite end portions) of the light-emitting elements ED disposed in the first sub-pixel SPX1 and electrode contact holes CTD and CTS; and FIG. 6 shows a cross section passing through the end portions (e.g., opposite end portions) of the light-emitting elements ED disposed in the first sub-pixel SPXn and contacts CT1 and CT2.

Referring to FIGS. 5 and 6 in conjunction with FIG. 4, the display device 10 may include a wiring substrate 101 including a first substrate SUB, and a semiconductor layer, conductive layers and insulating layers disposed thereon. For example, the display device 10 may include electrodes RME (e.g., RME1 and RME2), light-emitting elements ED, and connection electrodes CNE (e.g., CNE1 and CNE2) disposed on the wiring substrate 101. The semiconductor layer, the conductive layers and the insulating layers on the wiring substrate 101 may form a circuit layer of the display device 10.

The first substrate SUB may be an insulating substrate. The first substrate SUB may be made of an insulating material such as glass, quartz and a polymer resin. The first substrate SUB may be either a rigid substrate or a flexible substrate that is bendable, foldable, or rollable. The first substrate SUB may include the display area DPA and the non-display area NDA surrounding the display area DPA. The display area DPA may include the emission area EMA and the subsidiary area SA which is a portion of the non-emission area.

A first conductive layer may be disposed on the first substrate SUB. The first conductive layer may include a bottom metal layer BML. The bottom metal layer BML may be disposed to overlap an active layer ACT1 of a first transistor T1. The bottom metal layer BML may prevent light from being incident on the first active layer ACT1 of the first transistor or may be electrically connected to the first active layer ACT1 to stabilize the electrical characteristics of the first transistor T1. In another example, the bottom metal layer BML may be omitted.

A buffer layer BL may be disposed on the bottom metal layer BML and the first substrate SUB. The buffer layer BL may be formed on the first substrate SUB to protect the transistors of the pixel PX from moisture permeating through the first substrate SUB that is susceptible to moisture permeation, and may also provide a flat surface.

The semiconductor layer may be disposed on the buffer layer BL. The semiconductor layer may include the first active layer ACT1 of the first transistor T1 and the second active layer ACT2 of the second transistor T2. The first active layer ACT1 and the second active layer ACT2 may be disposed to partially overlap the first gate electrode G1 and the second gate electrode G2 of a second conductive layer, respectively, which will be described later.

The semiconductor layer may include polycrystalline silicon, monocrystalline silicon, an oxide semiconductor, etc. In other embodiments, the semiconductor layer may include polycrystalline silicon. The oxide semiconductor may be an oxide semiconductor including indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium-gallium zinc tin oxide (IGZTO), etc.

Although only one first transistor T1 is disposed in the sub-pixel SPXn of the display device 10 in the drawing, embodiments are not limited thereto. A larger number of transistors may be included in the display device 10.

A first gate insulating layer G1 may be disposed on the semiconductor layer and the buffer layer BL in the display area DPA. The first gate insulating layer G1 may not be disposed in the pad area PDA. The first gate insulating layer G1 may function/work as a gate insulating film of each of the transistors T1 and T2. Although the first gate insulating layer G1 is disposed (e.g., entirely disposed) on the buffer layer BL in the example shown in the drawings, embodiments are not limited thereto. In some embodiments, the first gate insulating layer G1 may be patterned together with the gate electrodes G1 and G2 of the second conductive layer to be described later, and may be partially disposed between the second conductive layer and the active layers ACT1 and ACT2 of the semiconductor layer.

The second conductive layer may be disposed on the first gate insulating layer G1. The second conductive layer may include a first gate electrode G1 of the first transistor T1, and a second gate electrode G2 of the second transistor T2. The first gate electrode G1 may overlap a channel region of the first active layer ACT1 in the third direction DR3, which is the thickness direction. The second gate electrode G2 may overlap a channel region of the second active layer ACT2 in the third direction DR3, which is the thickness direction. For example, the second conductive layer may further include an electrode of a storage capacitor Cst.

A first interlayer dielectric layer IL1 may be disposed on the second conductive layer. The first interlayer dielectric layer IL1 may function/work as an insulating film between the second conductive layer and other layers disposed thereon and may protect the second conductive layer.

The third conductive layer may be disposed on the first interlayer dielectric layer IL1. The third conductive layer may include the first voltage line VL1 and the second voltage line VL2 disposed in the display area DPA, a first conductive pattern layer CDP1, and the source electrodes S1 and S2 and drain electrodes D1 and D2 of the transistors T1 and T2. For example, the third conductive layer may further include the other electrode of the storage capacitor Cst.

A high-level voltage (or a first supply voltage) may be applied to the first voltage line VL1 to be transferred to the first electrode RME1, and a low-level voltage (or a second supply voltage) may be applied to the second voltage line VL2 to be transferred to the second electrode RME2. A portion of the first voltage line VL1 may be in contact with the first active layer ACT1 of the first transistor T1 through a contact hole penetrating (or passing through) the first interlayer dielectric layer IL1 and the first gate insulating layer G1. The first voltage line VL1 may function/work as the first drain electrode D1 of the first transistor T1. The second voltage line VL2 may be connected (e.g., directly connected) to the second electrode RME2 to be described later.

The first conductive pattern layer CDP1 may be in contact with the first active layer ACT1 of the first transistor T1 through a contact hole penetrating (or passing through) the first interlayer dielectric layer IL1 and the first gate insulating layer G1. The first conductive pattern layer CDP1 may be in contact with the bottom metal layer BML through another contact hole. The first conductive pattern layer CDP1 may function/work as a first source electrode S1 of the first transistor T1. For example, the first conductive pattern layer CDP1 may be connected to a first electrode RME1 or a first connection electrode CNE1 to be described later. The first transistor T1 may transfer the first supply voltage applied from the first voltage line VL1 to the first electrode RME1 or the first connection electrode CNE1.

The second source electrode S2 and the second drain electrode D2 may be in contact with the second active layer ACT2 of the second transistor T2 through contact holes penetrating (or passing through) the first interlayer dielectric layer IL1 and the first gate insulating layer G1, respectively. The second transistor T2 may be one of the switching transistors described above with reference to FIG. 3. The second transistor T2 may transmit a signal applied from the data line DTL of FIG. 3 to the first transistor T1 or may transmit a signal applied from the initialization voltage line VIL of FIG. 3 to the other electrode of the storage capacitor Cst.

A first passivation layer PV1 may be disposed over the third conductive layer. The first passivation layer PV1 may function/work as an insulating film between the third conductive layer and other layers and may protect the third conductive layer.

The buffer layer BL, the first gate insulating layer G1, the first interlayer dielectric layer IL1, and the first passivation layer PV1 may be made up of multiple inorganic layers alternately stacked on one another. For example, the buffer layer BL, the first gate insulating layer G1, the first interlayer dielectric layer IL1 and the first passivation layer PV1 may be made up of a double layer in which inorganic layers including at least one of silicon oxide (SiOₓ), silicon nitride (SiNₓ) and silicon oxynitride (SiOₓN_{y}) are stacked on one another or multiple layers in which they are alternately stacked on one another. However, embodiments are not limited thereto. The buffer layer BL, the first gate insulating layer G1, the first interlayer dielectric layer IL1 and the first passivation layer PV1 may be made up of a single inorganic layer including the above-described insulating material. In some embodiments, the first interlayer dielectric layer IL1 may be made of an organic insulating material such as polyimide (PI).

A via layer VIA may be disposed on the third conductive layer in the display area DPA. The via layer VIA may include an organic insulating material, e.g., an organic insulating material such as polyimide (PI), to provide a flat surface over the underlying conductive layers having different heights. In another example, the via layer VIA may be omitted in some implementations.

The display device 10 may include the bank pattern layers BP1 and BP2, electrodes RME (e.g., RME1 and RME2), the bank layer BNL, the light-emitting elements ED, and the connection electrodes CNE (e.g., CNE1 and CNE2), as a display element layer disposed on the via layer VIA of the wiring substrate 101. For example, the display device 10 may include insulating layers PAS1, PAS2, and PAS3 disposed on the wiring substrate 101.

The bank pattern layers BP1 and BP2 may be disposed in the emission area EMA of each sub-pixel SPX. Each of the bank pattern layers BP1 and BP2 may have a shape that has a constant width in the second direction DR2 and extends in the first direction DR1.

For example, the bank pattern layers BP1 and BP2 may include a first bank pattern layer BP1 and a second bank pattern layer BP2 spaced apart from each other in the second direction DR2 in the emission area EMA of each sub-pixel SPXn. The first bank pattern layer BP1 may be disposed on the left side of the center portion of the emission area EMA that is a side in the second direction DR2, and the second bank pattern layer BP2 may be spaced apart from the first bank pattern layer BP1 and may be disposed on the right side of the center portion of the emission area EMA that is the opposite side in the second direction DR2. The first bank pattern layer BP1 and the second bank pattern layer BP2 may be alternately arranged along the second direction DR2 and may be disposed in an island-like pattern in the display area DPA. The light-emitting elements ED may be disposed between the first bank pattern layer BP1 and the second bank pattern layer BP2.

The length of the first bank pattern layer BP1 may be substantially equal to the length of the second bank pattern layer BP2 in the first direction DR1. The lengths of the first bank pattern layer BP1 and the second bank pattern layer BP2 may be smaller than the length of the emission area EMA surrounded by the bank layer BNL in the first direction DR1. The first bank pattern layer BP1 and the second bank pattern layer BP2 may be spaced apart from a portion of the bank layer BNL that extends in the second direction DR2. However, embodiments are not limited thereto. The bank pattern layers BP1 and BP2 may be integral with the bank layer BNL or may partially overlap a portion of the bank layer BNL that extends in the second direction DR2. In another example, the lengths of the bank pattern layers BP1 and BP2 in the first direction DR1 may be substantially equal to or greater than the length of the emission area EMA surrounded by the bank layer BNL in the first direction DR1.

The first bank pattern layer BP1 and the second bank pattern layer BP2 may have the same width in the second direction DR2. However, embodiments are not limited thereto. In another example, the first bank pattern layer BP1 and the second bank pattern layer BP2 may have different widths. For example, one of the bank pattern layers may have a greater width than another one, and the larger bank pattern layer may be disposed across the emission areas EMA of different sub-pixels SPXn adjacent to each other in the second direction DR2. In this instance, in case that the bank pattern layers are disposed across the emission areas EMA, portions of the bank layer BNL extending in the first direction DR1 may overlap the second bank pattern layer BP2 in the thickness direction. Although two bank pattern layers BP1 and BP2 are disposed in each sub-pixel SPXn and have the same width in the example shown in the drawings, embodiments are not limited thereto. The number and shape of the bank pattern layers BP1 and BP2 may vary according to the number or arrangement structure of the electrodes RME.

The bank pattern layers BP1 and BP2 may be disposed on the via layer VIA. For example, the bank pattern layers BP1 and BP2 may be disposed (e.g., directly disposed) on the via layer VIA, and may have a structure that at least partly protrudes from the upper surface of the via layer VIA. The protruding portions of the bank pattern layers BP1 and BP2 may have inclined or bent side surfaces. The lights emitted from the light-emitting elements ED may be reflected by the electrodes RME disposed on the bank pattern layers BP1 and BP2 so that the lights may emit/exit toward the upper side of the via layer VIA. For example, the bank pattern layers BP1 and BP2 may have a semi-circular or semi-elliptical shape with a curved outer surface in the cross-sectional view. The bank pattern layers BP1 and BP2 may include an organic insulating material such as polyimide (PI), but embodiments are not limited thereto.

The electrodes RME (e.g., RME1 and RME2) may have a shape extending in a direction and may be disposed in each of the sub-pixels SPXn. The electrodes RME1 and RME2 may extend in the first direction DR1 to be disposed in the emission area EMA and the subsidiary area SA of the sub-pixel SPXn, and the electrodes RME (e.g., RME1 and RME2) may be spaced apart from one another in the second direction DR2. The electrodes RME may be electrically connected to the light-emitting elements ED, which will be described later. However, embodiments are not limited thereto. For example, the electrodes RME (e.g., RME1 and RME2) may not be electrically connected to the light-emitting elements ED.

The display device 10 may include a first electrode RME1 and a second electrode RME2 disposed in each of the sub-pixels SPXn. The first electrode RME1 may be disposed on the left side of the center portion of the emission area EMA, and the second electrode RME2 may be spaced apart from the first electrode RME1 in the second direction DR2 and may be disposed on the right side of the center portion of the emission area EMA. The first electrode RME1 may be disposed on the first bank pattern layer BP1, and the second electrode RME2 may be disposed on the second bank pattern layer BP2. The first electrode RME1 and the second electrode RME2 may extend beyond the bank layer BNL and may be partially disposed in the sub-pixel SPXn and the subsidiary area SA. The first electrode RME1 and the second electrode RME2 of a sub-pixel SPXn may be spaced apart from those of another sub-pixel SPXn at the separation region ROP positioned in the subsidiary area SA of one of the sub-pixels SPXn.

Although two electrodes RME are disposed in each sub-pixel SPXn and have a shape extending in the first direction DR1 in the drawings, embodiments are not limited thereto. The electrodes RME may be disposed, or the electrodes RME may be partially bent, and may have shapes having different widths at different positions.

The first electrode RME1 and the second electrode RME2 may be disposed on at least inclined side surfaces of the bank pattern layers BP1 and BP2. According to an embodiment, the width of the electrodes RME measured in the second direction DR2 may be smaller than the width of the bank pattern layers BP1 and BP2 measured in the second direction DR2. The distance between the first electrode RME1 and the second electrode RME2 spaced apart from each other in the second direction DR2 may be smaller than the distance between the bank pattern layers BP1 and BP2. At least a portion of the first electrode RME1 and at least a portion of the second electrode RME2 may be disposed (e.g., directly disposed) on the via layer VIA, e.g., on the same plane.

The light-emitting elements ED disposed between the bank pattern layers BP1 and BP2 may emit lights through the end portions (e.g., opposite end portions). The emitted lights may be directed/transmitted to the electrodes RME disposed on the bank pattern layers BP1 and BP2. The portion of each of the electrodes RME that is disposed on the bank pattern layers BP1 and BP2 may reflect lights emitted from the light-emitting elements ED. The first electrodes RME1 and the second electrodes RME2 may be disposed to cover the side surfaces of the bank pattern layers BP1 and BP2 on at least one side to reflect lights emitted from the light-emitting elements ED.

Each of the electrodes RME may be in contact with (e.g., in direct contact with) the third conductive layer through the electrode contact holes CTD and CTS where it overlaps the bank layer BNL between the emission area EMA and the subsidiary area SA. The first electrode contact hole CTD may be formed where the bank layer BNL and the first electrode RME1 overlap each other. The second electrode contact hole CTS may be formed where the bank layer BNL and the second electrode RME2 overlap each other. The first electrode RME1 may be in contact with the first conductive pattern layer CDP1 through the first electrode contact hole CTD penetrating (or passing through) the via layer VIA and the first passivation layer PV1. The second electrode RME2 may be in contact with the second voltage line VL2 through the second electrode contact hole CTS penetrating (or passing through) the via layer VIA and the first passivation layer PV1. The first electrode RME1 may be electrically connected to the first transistor T1 through the first conductive pattern layer CDP1 to receive the first supply voltage. The second electrode RME2 may be electrically connected to the second voltage line VL2 to receive the second supply voltage. However, embodiments are not limited thereto. According to another embodiment, each of the first and second electrodes RME1 and RME2 may not be electrically connected to the voltage lines VL1 and VL2 of the third conductive layer and connection electrodes CNE to be described later may be connected (e.g., directly connected) to the third conductive layer.

Each of the electrodes RME may include a conductive material having a high reflectance. For example, the electrodes RME may include a metal such as silver (Ag), copper (Cu) and aluminum (Al), or may include an alloy including aluminum (Al), nickel (Ni), lanthanum (La), or the like, or a stack of a metal layer such as titanium (Ti), molybdenum (Mo) and niobium (Nb) and the alloy. In some embodiments, the electrodes RME may be made up of a double-layer or a multi-layer in which an alloy including aluminum (Al) and at least one metal layer made of titanium (Ti), molybdenum (Mo) and niobium (Nb) are stacked on one another.

However, embodiments are not limited thereto. The electrodes RME may further include a transparent conductive material. For example, each of the electrodes RME may include a material such as ITO, IZO and ITZO. In some embodiments, each of the first and second electrodes RME1 and RME2 may have a structure in which one or more layers of a transparent conductive material and one or more metal layers having high reflectivity are stacked on one another, or may be made up of a single layer including them. For example, each of the electrodes RME may have a stack structure such as ITO/Ag/ITO, ITO/Ag/IZO, or ITO/Ag/ITZO/IZO. The electrodes RME may be electrically connected to the light-emitting elements ED and may reflect some of the lights emitted from the light-emitting elements ED toward the upper side of the first substrate SUB.

The first insulating layer PAS1 may be disposed on the front surface of the display area DPA, and may be disposed on the via layer VIA and the electrodes RME. The first insulating layer PAS1 may protect the electrodes RME and may insulate different electrodes RME from each other. As the first insulating layer PAS1 is disposed to cover the electrodes RME before the bank layer BNL is formed, the electrode RME may be prevented from being damaged during the process of forming the bank layer BNL. For example, the first insulating layer PAS1 may also prevent the light-emitting elements ED disposed thereon from being brought into contact with other elements and damaged.

In an embodiment, the first insulating layer PAS1 may have a step portion so that a portion of the upper surface is recessed between the electrodes RME spaced apart from one another in the second direction DR2. The light-emitting elements ED may be disposed on the upper surface of the step portion of the first insulating layer PAS1, and a space may be formed between the light-emitting elements ED and the first insulating layer PAS1.

The bank layer BNL may be disposed on the first insulating layer PAS1. The bank layer BNL may include portions extending in the first direction DR1 and the second direction DR2 and may surround each of the sub-pixels SPXn. The bank layer BNL may surround the emission area EMA and the subsidiary area SA of each of the sub-pixels SPXn to distinguish between the emission area EMA and the subsidiary area SA thereof, and may surround the border area of the display area DPA to distinguish between the display area DPA and the non-display area NDA. The bank layer BNL may be disposed in the entire display area DPA to form a lattice pattern. The area opened by the bank layer BNL in the display area DPA may be the emission area EMA and the subsidiary area SA.

The bank layer BNL may have a certain height similar to the bank pattern layers BP1 and BP2. In some embodiments, the top surface of the bank layer BNL may have a height higher than that of the bank pattern layers BP1 and BP2, and the thickness of the bank layer BNL may be substantially equal to or greater than the thicknesses of the bank pattern layers BP1 and BP2. The bank layer BNL may prevent an ink from overflowing into adjacent sub-pixels SPXn during an inkjet printing process for fabricating the display device 10. The bank layer BNL may include an organic insulating material such as polyimide, like the bank pattern layers BP1 and BP2.

The light-emitting elements ED may be disposed in the emission area EMA. The light-emitting elements ED may be disposed between the bank pattern layers BP1 and BP2 and may be spaced apart from one another in the first direction DR1. According to an embodiment, the light-emitting elements ED may have a shape extending in a direction, and the end portions (e.g., opposite end portions) of light-emitting elements ED may be disposed on different electrodes RME, respectively. The length of the light-emitting elements ED may be larger than the distance between the electrodes RME spaced apart from each other in the second direction DR2. The direction in which the light-emitting elements ED generally extend may be perpendicular to the first direction DR1 in which the electrodes RME extends. However, embodiments are not limited thereto. The direction in which the light-emitting elements ED extends may face the second direction DR2 or a direction obliquely thereto.

The light-emitting elements ED may be disposed on the first insulating layer PAS1. The light-emitting elements ED may extend in a direction, and the direction may be parallel to the upper surface of the first substrate SUB. As will be described later, the light-emitting elements ED may include semiconductor layers arranged in the extension direction. The semiconductor layers may be sequentially arranged along a direction parallel to the upper surface of the first substrate SUB. However, embodiments are not limited thereto. In case that the light-emitting elements ED have a different structure, semiconductor layers may be disposed in a direction perpendicular to the first substrate SUB.

The light-emitting elements ED disposed in each of the sub-pixels SPXn may emit light of different wavelength bands according to the material of the semiconductor layer. However, embodiments are not limited thereto. The light-emitting elements ED disposed in each of the sub-pixels SPXn may include the semiconductor layers made of the same material and may emit light of the same color.

The light-emitting elements ED may be electrically connected to the electrodes RME and the conductive layers under the via layer VIA in contact with the connection electrodes CNE (e.g., CNE1 and CNE2), and an electric signal may be applied to the light-emitting elements ED so that light of a certain wavelength range may be emitted.

The second insulating layer PAS2 may be disposed on the light-emitting elements ED, the first insulating layer PAS1, and the bank layer BNL. The second insulating layer PAS2 may extend in the first direction DR1 between the bank pattern layers BP1 and BP2 and may include a pattern portion disposed on the light-emitting elements ED. The pattern portion may be disposed to partially surround the outer surface of the light-emitting elements ED, and may not cover sides (e.g., opposite sides) or end portions (e.g., opposite end portions) of the light-emitting elements ED. The pattern portion may form a linear pattern or an island pattern in each sub-pixel SPXn when viewed from the top (or in plan view). The pattern portion of the second insulating layer PAS2 may protect the light-emitting elements ED and may fix the light-emitting elements ED during the process of fabricating the display device 10. For example, the second insulating layer PAS2 may be disposed to fill the space between light-emitting elements ED and the second insulating layer PAS2 thereunder. For example, a portion of the second insulating layer PAS2 may be disposed on the bank layer BNL and in the subsidiary area SA.

The connection electrodes CNE (e.g., CNE1 and CNE2) may be disposed on the electrodes RME and the bank pattern layers BP1 and BP2. The connection electrodes CNE may each have a shape extending in a direction and may be spaced apart from one another. The connection electrodes CNE may be in contact with the light-emitting elements ED and may be electrically connected to the third conductive layer.

The connection electrodes CNE may include a first connection electrode CNE1 and a second connection electrode CNE2 disposed in each sub-pixel SPXn. The first connection electrode CNE1 may have a shape extending in the first direction DR1 and may be disposed on the first electrode RME1 or the first bank pattern layer BP1. The first connection electrode CNE1 may partially overlap the first electrode RME1 and may be disposed from the emission area EMA to the subsidiary area SA beyond the bank layer BNL. The second connection electrode CNE2 may have a shape extending in the first direction DR1 and may be disposed on the second electrode RME2 or the second bank pattern layer BP2. The second connection electrode CNE2 may partially overlap the second electrode RME2 and may be disposed from the emission area EMA to the subsidiary area SA beyond the bank layer BNL. The first connection electrode CNE1 and the second connection electrodes CNE2 may be in contact with the light-emitting elements ED and may be electrically connected to the electrodes RME or a conductive layer thereunder.

For example, the first connection electrode CNE1 and the second connection electrode CNE2 may be disposed on the side surfaces of the second insulating layer PAS2, respectively, and may be in contact with the light-emitting elements ED. The first connection electrode CNE1 may partially overlap the first electrode RME1 and may be in contact with first end portions of the light-emitting elements ED. The second connection electrode CNE2 may partially overlap the second electrode RME2 and may be in contact with second end portions of the light-emitting elements ED. The connection electrodes CNE may be disposed across the emission area EMA and the subsidiary area SA. A portion of each of the connection electrodes CNE that is disposed in the emission area EMA may be in contact with the light-emitting elements ED, and a part thereof that is disposed in the subsidiary area SA may be electrically connected to the third conductive layer.

In the display device according to the embodiment, each of the connection electrodes CNE may be in contact with the electrodes RME through the contacts CT1 and CT2 positioned in the subsidiary area SA. The first connection electrode CNE1 may be in contact with the first electrode RME1 through the first contact CT1 penetrating (or passing through) the first insulating layer PAS1, the second insulating layer PAS2 and the third insulating layer PAS3 in the subsidiary area SA. The second connection electrode CNE2 may be in contact with the second electrode RME1 through the second contact CT2 penetrating (or passing through) the first insulating layer PAS1 and the second insulating layer PAS2 in the subsidiary area SA. The connection electrodes CNE may be electrically connected to the third conductive layer through the respective electrodes RME. The first connection electrode CNE1 may be electrically connected to the first transistor T1 to apply the first supply voltage, and the second connection electrode CNE2 may be electrically connected to the second voltage line VL2 to apply the second supply voltage. Each of the connection electrodes CNE may be in contact with the light-emitting elements ED in the emission area EMA to transmit the supply voltage to the light-emitting elements ED.

However, embodiments are not limited thereto. In some embodiments, the connection electrodes CNE may be in contact with (e.g., in direct contact with) the third conductive layer, or may be electrically connected to the third conductive layer through other pattern layers than the electrodes RME.

The connection electrodes CNE may include a conductive material. For example, the connection electrodes CNE may include ITO, IZO, ITZO, aluminum (Al), etc. For example, the connection electrodes CNE may include a transparent conductive material, and lights emitted from the light-emitting elements ED may transmit the connection electrodes CNE to exit.

The third insulating layer PAS3 may be disposed on the second connection electrode CNE2 and the second insulating layer PAS2. The third insulating layer PAS3 may be disposed (e.g., entirely disposed) on the second insulating layer PAS2 to cover the second connection electrode CNE2. The first connection electrode CNE1 may be disposed on the third insulating layer PAS3. The third insulating layer PAS3 may be disposed (e.g., entirely disposed) on the via layer VIA except for the position where the second connection electrode CNE2 is disposed. The third insulating layer PAS3 may insulate the first connection electrode CNE1 and the second connection electrode CNE2 from each other so that they may not be in direct contact with each other.

For example, another insulating layer may be further disposed on the third insulating layer PAS3 and the first connection electrode CNE1. The insulating layer may protect the elements disposed on the first substrate SUB against the external environment.

Each of the above-described first insulating layer PAS1, second insulating layer PAS2 and third insulating layer PAS3 may include an inorganic insulating material or an organic insulating material. For example, each of the first insulating layer PAS1, the second insulating layer PAS2 and the third insulating layer PAS3 may include an inorganic insulating material. In another example, the first insulating layer PAS1 and the third insulating layer PAS3 may include an inorganic insulating material, and the second insulating layer PAS2 may include an organic insulating material. Each of the first insulating layer PAS1, the second insulating layer PAS2 and the third insulating layer PAS3 or at least one of them may be formed in a structure in which insulating layers are alternately or repeatedly stacked on one another. According to an embodiment, each of the first insulating layer PAS1, the second insulating layer PAS2 and the third insulating layer PAS3 may be made of at least one of silicon oxide (SiOₓ), silicon nitride (SiNₓ), and silicon oxynitride (SiOₓN_{y}). The first insulating layer PAS1, the second insulating layer PAS2 and the third insulating layer PAS3 may be made of the same material. In another example, some of them may be made of the same material, and the other(s) may be made of different material(s), or they may be made of different materials.

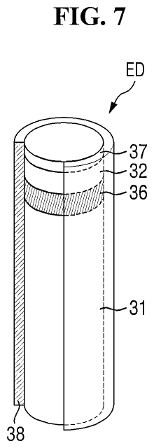

FIG. 7 is a schematic view showing a light-emitting element according to an embodiment.

Referring to FIG. 7, a light-emitting element ED may be a light-emitting diode. For example, the light-emitting element ED may have a size in a range of nanometers to micrometers and may be an inorganic light-emitting diode made of an inorganic material. The light-emitting element ED may be aligned between two electrodes facing each other as polarities are generated by forming an electric field in a certain direction between the two electrodes.

The light-emitting element ED according to an embodiment may have a shape extending in a direction. The light-emitting element ED may have a shape of a cylinder, a rod, a wire, a tube, etc. It is to be understood that the shape of the light-emitting element ED is not limited thereto. The light-emitting element ED may have a variety of shapes including a polygonal column shape such as a cube, a cuboid and a hexagonal column, or a shape that extends in a direction with partially inclined outer surfaces.

The light-emitting element ED may include semiconductor layers doped with a dopant of a conductive type (e.g., p-type or n-type). The semiconductor layers may emit light of a certain wavelength band by transmitting an electric signal applied from an external power source. The light-emitting element ED may include a first semiconductor layer 31, a second semiconductor layer 32, an emissive layer 36, an electrode layer 37, and an insulating film 38.

The first semiconductor layer 31 may be an n-type semiconductor. The first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be one or more of AlGaInN, GaN, AlGaN, InGaN, AlN and InN doped with n-type dopant. The n-type dopant doped into the first semiconductor layer 31 may be Si, Ge, Se, Sn, etc.

The second semiconductor layer 32 may be disposed above the first semiconductor layer 31 with the emissive layer 36 therebetween. The second semiconductor layer 32 may be a p-type semiconductor, and may include a semiconductor material having the following chemical formula: AlₓGa_{y}In_{1-x-y}N (0≤x≤1, 0≤y≤1, 0≤x+y≤1). For example, the second semiconductor layer 32 may be one or more of AlGaInN, GaN, AlGaN, InGaN, AlN and InN doped with p-type dopant. The p-type dopant doped into the second semiconductor layer 32 may be Mg, Zn, Ca, Ba, etc.

Although each of the first semiconductor layer 31 and the second semiconductor layer 32 is implemented as a signal layer in the drawings, embodiments are not limited thereto. According to the material of the emissive layer 36, the first semiconductor layer 31 and the second semiconductor layer 32 may further include a larger number of layers, e.g., a clad layer or a tensile strain barrier reducing (TSBR) layer. For example, the light-emitting elements ED may further include another semiconductor layer disposed between the first semiconductor layer 31 and the emissive layer 36 or between the second semiconductor layer 32 and the emissive layer 36. The semiconductor layer disposed between the first semiconductor layer 31 and the emissive layer 36 may be one or more of AlGaInN, GaN, AlGaN, InGaN, AlN, InN and SLs doped with an n-type dopant. The semiconductor layer disposed between the second semiconductor layer 32 and the emissive layer 36 may be one or more of AlGaInN, GaN, AlGaN, InGaN, AlN, and InN doped with a p-type dopant.

The emissive layer 36 may be disposed between the first semiconductor layer 31 and the second semiconductor layer 32. The emissive layer 36 may include a material having a single or multiple quantum well structure. In case that the emissive layer 36 includes a material having the multiple quantum well structure, the structure may include quantum layers and well layers alternately stacked on one another. The emissive layer 36 may emit light as electron-hole pairs are combined therein in response to an electrical signal applied through the first semiconductor layer 31 and the second semiconductor layer 32. The emissive layer 36 may include a material such as AlGaN, AlGaInN, and InGaN. For example, in case that the emissive layer 36 has a multi-quantum well structure in which quantum layers and well layers are alternately stacked on one another, the quantum layers may include AlGaN or AlGaInN, and the well layers may include a material such as GaN and AlGaN.

The emissive layer 36 may have a structure in which a semiconductor material having a large band gap energy and a semiconductor material having a small band gap energy are alternately stacked on one another, and may include other Group III to Group V semiconductor materials according to the wavelength range of the emitted light. Accordingly, the light emitted from the emissive layer 36 is not limited to the light of the blue wavelength band. The emissive layer 36 may emit light of red or green wavelength band in some implementations.

The electrode layer 37 may be an ohmic connection electrode. However, embodiments are not limited thereto. The electrode layer 37 may be a Schottky connection electrode. The light-emitting element ED may include at least one electrode layer 37. The light-emitting element ED may include one or more electrode layers 37. However, embodiments are not limited thereto. The electrode layer 37 may be omitted.

The electrode layer 37 may reduce the resistance between the light-emitting element ED and the electrodes or the connection electrodes in case that the light-emitting element ED is electrically connected to the electrodes or the connection electrodes in the display device 10. The electrode layer 37 may include a metal having conductivity. For example, the electrode layer 37 may include at least one of aluminum (Al), titanium (Ti), indium (In), gold (Au), silver (Ag), ITO, IZO and ITZO.

The insulating film 38 may be disposed to surround the outer surfaces of the semiconductor layers and electrode layers described above. For example, the insulating film 38 may be disposed to surround at least the outer surface of the emissive layer 36, and may expose end portions (e.g., opposite end portions) of the light-emitting element ED in the longitudinal direction. For example, a portion of the upper surface of the insulating film 38 may be rounded in cross section, which is adjacent to at least one of the end portions of the light-emitting element ED.

The insulating film 38 may include materials having insulating properties, for example, at least one of: silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). Although the insulating film 38 is formed as a single layer in the drawings, embodiments are not limited thereto. In some embodiments, the insulating film 38 may be made up of a multilayer structure in which multiple layers are stacked on one another.

The insulating film 38 may protect the semiconductor layers and the electrode layer of the light-emitting elements ED. The insulating film 30 may prevent an electrical short-circuit that occurs in the emissive layer 36 in case that it comes in direct contact with an electrode through which an electric signal is transferred to the light-emitting element ED. For example, the insulating film 38 may prevent a decrease in luminous efficiency.

For example, the outer surface of the insulating film 38 may be processed by a surface treatment. The light-emitting elements ED may be dispersed in an ink, and the ink may be sprayed onto the electrode. In doing so, a surface treatment may be applied to the insulating film 38 so that the insulating film 38 may become hydrophobic or hydrophilic in order to keep the light-emitting elements ED dispersed in the ink from being aggregated with one another.

The light-emitting elements ED may be fabricated by growing semiconductor layers on a wafer to form the electrode layer 37 and the insulating film 38, and by separating the light-emitting elements ED from the wafer. In case that the light-emitting elements ED are separated from the wafer, some of the light-emitting elements ED may be long or short, and thus the particle size of the light-emitting elements ED may become non-uniform (or different). In case that the particle size of the light-emitting elements ED is non-uniform (or different), structural problems may occur, e.g., the light-emitting elements ED may not be connected to the connection electrodes CNE or may not be properly aligned on the substrate SUB, which causes defects. To solve such problems, by sorting out light-emitting elements ED having different sizes (or non-uniform particle sizes) among light-emitting elements ED, the light-emitting elements ED may have a uniform particle size (or substantially same particular sizes).

Hereinafter, a particle separating apparatus that separates light-emitting elements ED of different particle sizes is disclosed.

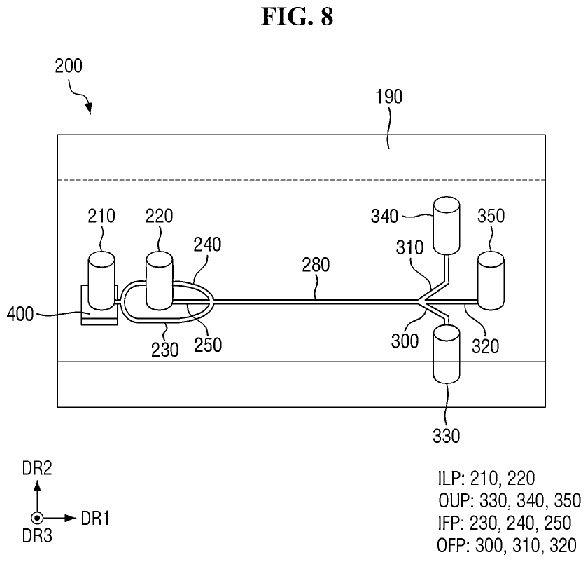

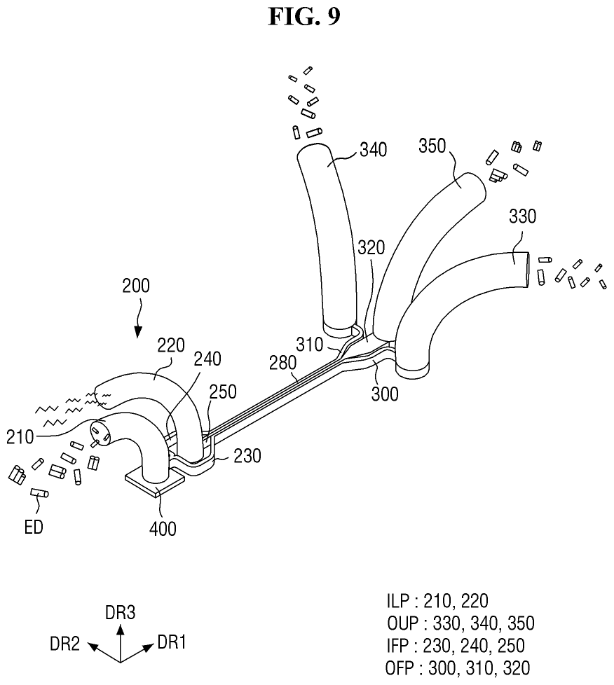

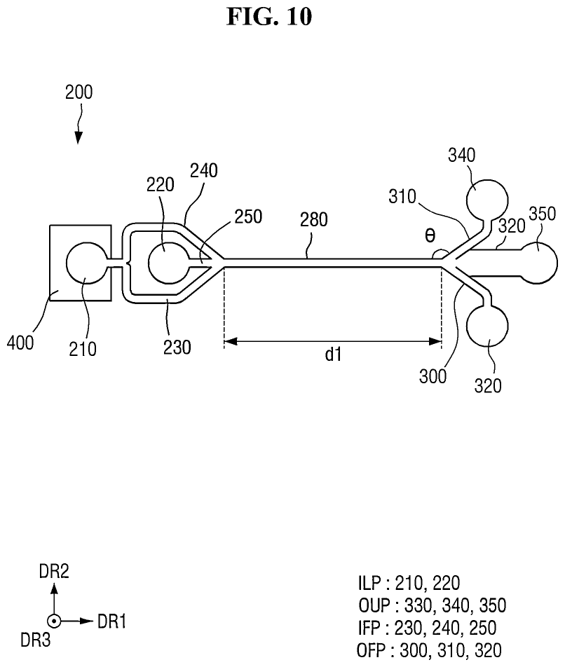

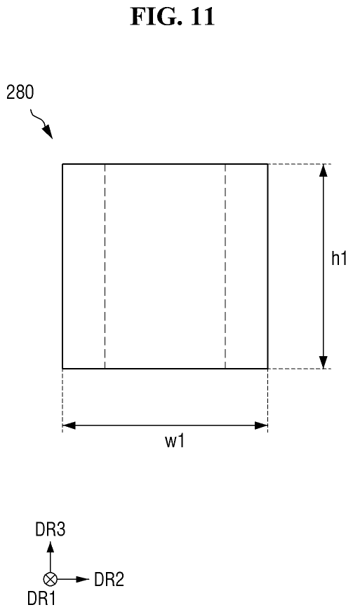

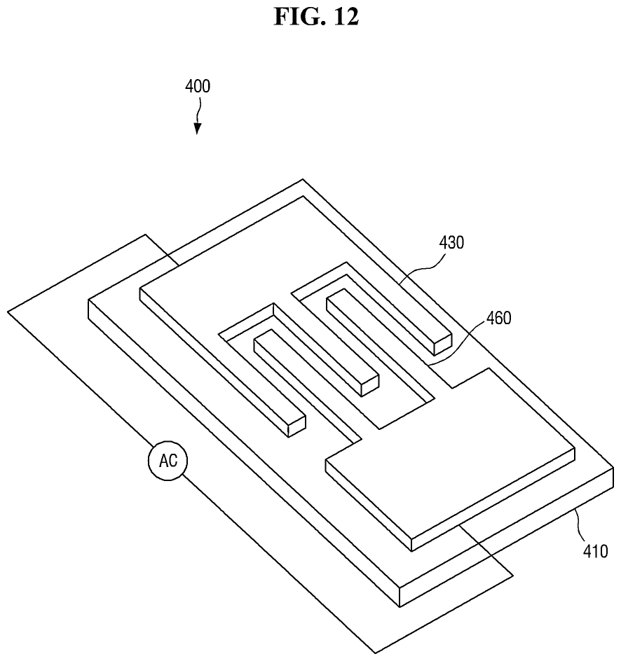

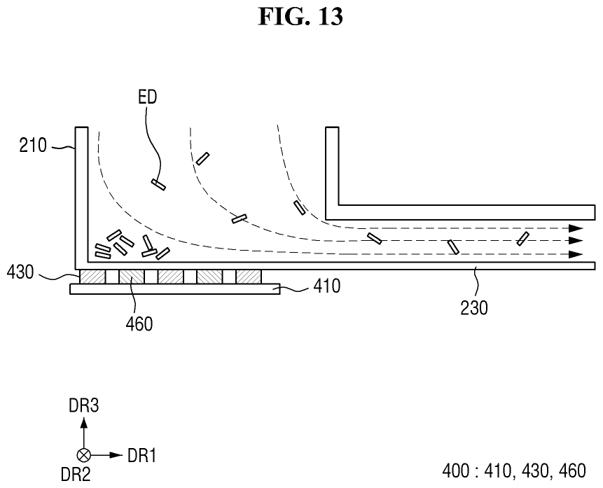

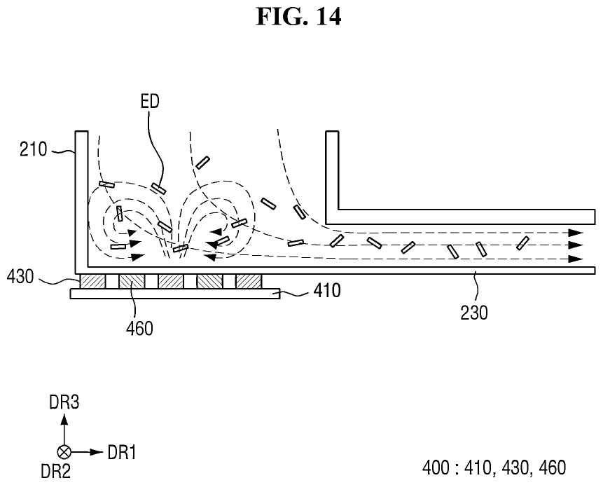

FIG. 8 is a schematic perspective view showing a particle separating apparatus according to an embodiment. FIG. 9 is a schematic perspective view showing the structure of the particle separating apparatus of FIG. 8 excluding the body. FIG. 10 is a schematic plan view showing the particle separating apparatus of FIG. 9. FIG. 11 is a schematic cross-sectional view showing a micro channel of the particle separating apparatus of FIG. 9. FIG. 12 is a schematic perspective view showing a vortex generator of the particle separating apparatus of FIG. 9. FIG. 13 is a schematic view showing the first inlet in case that the vortex generator of the particle separating apparatus of FIG. 9 is not in operation. FIG. 14 is a schematic view showing the first inlet in case that the vortex generator of the particle separating apparatus of FIG. 9 is in operation.

Referring to FIGS. 8 to 14, the particle separating apparatus 200 may be a microfluidic chip that separates the light-emitting elements ED according to sizes thereof. The particle separating apparatus 200 may include a base part 190, a micro channel 280 disposed in the base part 190, an inlet portion ILP (e.g., 210 and 220) disposed at an end portion of the micro channel 280, an inlet flow path IFP (e.g., 230, 240, and 250) connecting the inlet portion ILP and the micro channel 280, an outlet portion OUP (e.g., 330, 340, and 350) disposed at another end portion of the micro channel 280, an outlet flow path OFP (e.g., 300, 310, and 320) connecting the outlet portion OUP and the micro channel 280, and a vortex generator 400 disposed under the inlet portion ILP.

The base part 190 may form the body of the particle separating apparatus 200 and may be implemented in the form of a microfluidic chip. The micro channel 280, the inlet portion ILP, the inlet flow path IFP, the outlet portion OUP and the outlet flow path OPF may be disposed in the base part 190. For example, the vortex generator 400 may be disposed at the lower side of the base part 190.

The base part 190 may be fabricated by a mold injection process, a 3D printing process or the like. For example, the base part 190 may be fabricated by a process of producing a mold, injecting a paste mixed with polydimethylsiloxane (PDMS) and a curing agent into the mold, and then curing it.

The micro channel 280 may extend in a direction inside the base part 190. The micro channel 280 may be formed in a rectangular shape so that the lift force from the walls may act dominantly to facilitate separation of particles.

The micro channel 280 may have a certain length, a certain width and a certain height so that the light-emitting elements ED may be readily separated. The length d1 of the micro channel 280 may be about 15 nm to about 25 mm. With the length of the micro channel 280 in the above range, the light-emitting elements ED inside the micro channel 280 may readily reach an equilibrium position and provide sufficient length to overcome clastic lift force. For example, the micro channel 280 may have a ratio of height h1 to width w1 in the range of about 2 to about 3. With the ratio of the height h1 to the width w1 of the micro channel 280 in the above range, the interface between the viscoelastic fluid and the Newtonian fluid may be readily formed, and the light-emitting elements ED may be readily moved. The width w1 of the micro channel 280 may range from about 20 μm to about 30 μm, and the height h1 may range from about 50 μm to about 70 μm. According to an embodiment, the length d1 of the micro channel 280 may be about 15 mm, the width w1 may be about 20 μm, and the height h1 may be about 50 μm. However, embodiments are not limited thereto. The values may vary within the above ranges.

The inlet portion ILP may be disposed at an end portion of the micro channel 280. The inlet portion ILP may include a first inlet 210 and a second inlet 220 that are separated from each other. The first inlet 210 may be an injection port through which light-emitting elements ED and Newtonian fluid are injected. The first inlet 210 may be disposed farther from the micro channel 280 than the second inlet 220, but embodiments are not limited thereto. The second inlet 220 may be an injection port through which viscoelastic fluid (or non-Newtonian fluid) is injected. According to an embodiment, the density of the light-emitting elements ED may be about 4 g/cm³ to about 10 g/cm³. The Newtonian fluid may be Deionized (D1) water, and the viscoelastic fluid may be a polyethylene oxide (PEO) solution. The PEO solution may be a solution in which PEO is mixed with water, and the concentration of PEO may be about 50 ppm to about 300 ppm. The molecular weight of PEO may range from about 500 kDa to about 700 kDa. However, embodiments are not limited thereto. The Newtonian fluid may be used as alcohol, etc., or any other substances, which is used for the viscoelastic fluid.

The inlet flow path IFP may be disposed between the inlet portion ILP and the micro channel 280. The inlet flow path IFP may include a first inlet path (or first injection passage) 230, a second inlet path (or second injection passage) 240 and a third inlet path (or third injection passage) 250.

The first inlet path 230 and the second inlet path 240 may branch off from the first inlet 210 and may extend to the micro channel 280. The first inlet path 230 and the second inlet path 240 may be flow channels through which light-emitting elements ED and Newtonian fluid move. The first inlet path 230 and the second inlet path 240 may extend to surround the second inlet 220 with the second inlet 220 therebetween, e.g., in plan view.

The third inlet path 250 may extend from the second inlet 220 to the micro channel 280. The third inlet path 250 may be a flow channel through which viscoelastic fluid moves. The first inlet path 230, the second inlet path 240 and the third inlet path 250 may join/meet at an end portion of the micro channel 280.

The first inlet path 230 and the second inlet path 240 may each have a diameter of about 20 μm to about 40 μm. With the diameter of each of the first inlet path 230 and the second inlet path 240 within the above range, the light-emitting elements ED may be prevented from settling in the first inlet path 230 and the second inlet path 240. According to an embodiment, the first inlet path 230 and the second inlet path 240 may each have the diameter of about 20 μm.

The outlet flow portion OFP may be disposed between the outlet portion OUP and the micro channel 280. The outlet flow path OFP may include a first outlet path (or first discharge passage) 300, a second outlet path (or second discharge passage) 310 and a third outlet path (or third discharge passage) 320.

The first outlet path 300 may extend from the another end portion of the micro channel 280 to the first outlet 330 of the outlet portion OUP. The first outlet path 300 may be a flow channel through which the light-emitting elements ED and Newtonian fluid separated in the micro channel 280 move. The first outlet path 300 may be disposed on a side, e.g., on the right side of the micro channel 280 with respect to the direction of fluid flow inside the micro channel 280.

The second outlet path 310 may extend from the another end portion of the micro channel 280 to the second outlet 340 of the outlet portion OUP. The second outlet path 310 may be a flow channel through which the light-emitting elements ED and Newtonian fluid separated in the micro channel 280 move. The second outlet path 310 may be disposed on another side, e.g., on the left side of the micro channel 280 with respect to the direction of fluid flow inside the micro channel 280.

The third outlet path 320 may extend from the another end portion of the micro channel 280 to the third outlet 350 of the outlet portion OUP. The third outlet path 320 may be a flow channel through which the light-emitting elements ED and viscoelastic fluid separated in the micro channel 280 move. The third outlet path 320 may extend along the direction in which the micro channel 280 extends. The diameter of the third outlet path 320 may be larger than the diameters of the first outlet path 300 and the second outlet path 310. The diameter of the third outlet path 320 may be about 100 μm to about 300 μm. According to an embodiment, the diameter of the third outlet path 320 may be about 210 μm.

The angle θ formed by the micro channel 280 and the first outlet path 300 or the angle θ formed by the micro channel 280 and the second outlet path 310 may range from about 150° to about 165°. With the angle θ formed by the micro channel 280 and the first outlet path 300 or the angle θ formed by the micro channel 280 and the second outlet path 310 within the above range, it is possible to readily separate normal light-emitting elements EDN from abnormal light-emitting elements EDB.

The outlet portion OUP may be disposed at the another end portion of the micro channel 280. The outlet portion OUP may extend from the outlet flow path OPF connected to the another end portion of the micro channel 280. The outlet portion OUP may include a first outlet 330, a second outlet 340 and a third outlet 350 that are separated from each other.

The first outlet 330 may be a discharge port through which the light-emitting elements ED and Newtonian fluid are discharged. The first outlet 330 may extend from the first outlet path 300. The second outlet 340 may be a discharge port through which the light-emitting elements ED and Newtonian fluid are discharged. The second outlet 340 may extend from the second outlet path 310. The third outlet 350 may be a discharge port through which the light-emitting elements ED and viscoelastic fluid are discharged. The third outlet 350 may extend from the third outlet path 320.

Referring to FIG. 12, the vortex generator 400 may be disposed at the lower side of the base part 190. The vortex generator 400 may be disposed at the lower side of the base part 190 to overlap the first inlet 210 of the inlet portion ILP. The vortex generator 400 may generate a surface acoustic wave (SAW). A surface acoustic wave (SAW) may be an elastic wave traveling/transmitting along the surface of a material exhibiting elasticity. The surface acoustic wave may be an elastic wave that is represented as the sum of longitudinal waves, which propagate in parallel with the vibration direction of the particles vibrate, and transverse waves, which propagate in a direction perpendicular to the vibration direction of the particles. The vortex generator 400 may generate surface acoustic waves by converting an input electrical signal into a mechanical wave that propagates only over a solid surface. The vortex generator 400 may be an interdigital transducer (IDT). According to an embodiment, surface acoustic waves may be generated into the first inlet 210 from the lower side of the base part 190 that overlaps the first inlet 210.

The vortex generator 400 may include a piezoelectric substrate 410, a first element electrode 430 and a second element electrode 460 disposed on the piezoelectric substrate 410.

The piezoelectric substrate 410 may be made of a piezoelectric material such as lithium niobate (LiNbO₃), quartz (SiO₂) and barium titanate (BaTiO₃). A piezoelectric material may generate an electric signal in case that pressure is applied and may generate vibration in case that an electric signal is applied.

The first element electrode 430 and the second element electrode 460 may generate surface acoustic waves that are transmitted to the piezoelectric substrate 410 and propagate along the surface. For example, the first element electrode 430 and the second element electrode 460 may be implemented as interdigital transducer (IDT) electrodes. In case that an electric signal is applied to these electrodes, the piezoelectric substrate 410 may expand/contract due to the piezoelectric effect, thereby generating surface acoustic waves.

The first element electrode 430 and the second element electrode 460 may have a comb pattern. The frequency of the excited waves may be determined based on the pitch of the comb pattern. The first element electrode 430 may be disposed on a side of the piezoelectric substrate 410, and the second element electrode 460 may be disposed on the opposite side of the piezoelectric substrate 410. Each of the first element electrode 430 and the second element electrode 460 may have a branch shape, and the branches of each electrode may be arranged alternately with each other when viewed from the top (or in plan view).

The first element electrode 430 and the second element electrode 460 may include a conductive material. The conductive material may include, e.g., aluminum or gold. For example, the first element electrode 430 and the second element electrode 460 may further include a metal layer such as chromium to increase bonding strength with the piezoelectric substrate 410.

In case that an electric signal is applied to the first element electrode 430 and the second element electrode 460, a dynamic strain may occur in the piezoelectric substrate 410, and these elastic waves may travel/propagate in a perpendicular direction to the first and second element electrodes 430 and 460. Electric signals may be converted into surface acoustic waves by the piezoelectric effect. The electrical signal may be an alternating current (AC) electrical signal having a frequency in the radio frequency (RF) band. The speed of surface acoustic waves may be determined by the density and elastic coefficient of the piezoelectric substrate 410. According to an embodiment, the frequency used for surface acoustic waves may range from about 10 MHz to about 300 MHZ.

Referring to FIGS. 13 and 14, in case that light-emitting elements ED are injected together with Newtonian fluid into the first inlet 210 of the particle separating apparatus 200, light-emitting elements ED with a high density may settle down on the lower side of the first inlet 210. In case that an electric signal is applied to the first element electrode 430 and the second element electrode 460 of the vortex generator 400, a surface acoustic wave may be generated in the piezoelectric substrate 410 and may travel to the lower side of the first inlet 210. In case that a surface acoustic wave is transmitted to the Newtonian fluid, acoustic streaming that drives the flow of the Newtonian fluid may be generated. For example, a vortex flow may be generated in the Newtonian fluid by the acoustic streaming so that the settled light-emitting elements ED may be dispersed. Accordingly, settlement and aggregation of the light-emitting elements ED on the lower side of the first inlet 210 may be prevented or minimized.

The above-described particle separating apparatus 200 may separate light-emitting elements ED by using coronary micro-mechanics. Light-emitting elements ED may be fabricated by being grown on a wafer substrate and separated from the wafer substrate. In case that the light-emitting elements ED are separated from the wafer substrate, abnormal light-emitting elements EDB may be formed. For example, some of the light-emitting elements ED may be longer, or several of the light-emitting elements ED may stick (or be attached) together. Abnormal light-emitting elements EDB cause emission defects in the display device.

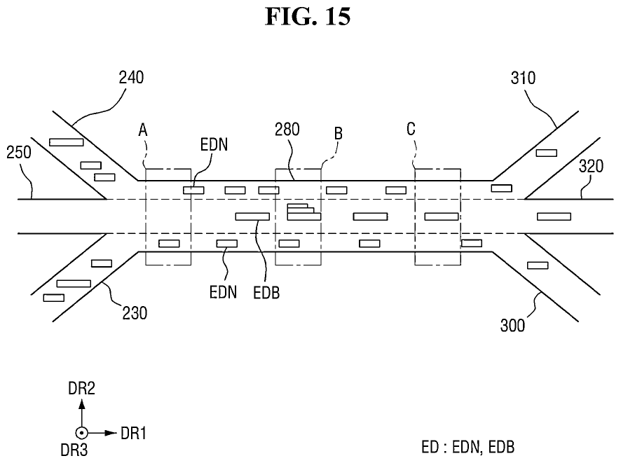

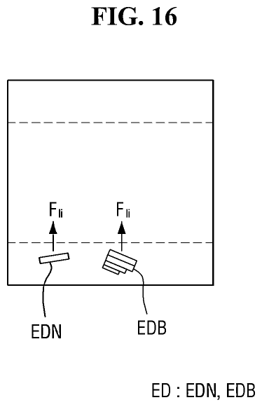

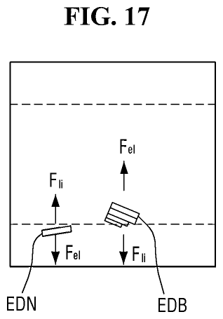

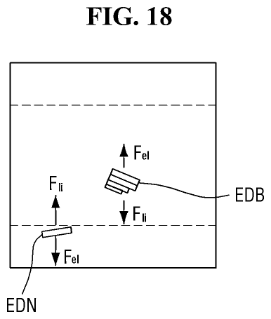

FIG. 15 is a schematic plan view showing a micro channel of a particle separating apparatus according to an embodiment. FIG. 16 is a schematic plan view showing area A of FIG. 15. FIG. 17 is a schematic plan view showing area B of FIG. 15. FIG. 18 is a schematic plan view showing area C of FIG. 15.

Referring to FIGS. 15, 16, 17, and 18 in conjunction with FIG. 9, a method of separating particles by using the particle separating apparatus 200 according to the embodiment will be described as follows:

The Newtonian fluid, in which the light-emitting elements ED are dispersed, may be injected into the first inlet 210 of the inlet portion ILP. By injecting the Newtonian fluid in which the light-emitting elements ED are dispersed at a flow rate in the range of about 20 μl/min to about 30 μl/min, the light-emitting elements ED may be separated more efficiently. A viscoelastic fluid may be injected into the second inlet 220 of the inlet portion ILP. The ratio of the flow rate of the Newtonian fluid in which the light-emitting elements ED are dispersed to the flow rate of the viscoelastic fluid may be in a range of about 3 to about 7.

The Newtonian fluid injected through the first inlet 210 may be injected into the micro channel 280 through the first inlet path 230 and the second inlet path 240. The viscoelastic fluid injected through the second inlet 220 may be injected into the micro channel 280 through the third inlet path 250.

In the vortex generator 400, alternating current (AC) electrical signals may be applied to the first and second element electrodes 430 and 460 to generate surface acoustic waves. Surface acoustic waves may travel to the first inlet 210 to generate acoustic streaming vortices in the Newtonian fluid at the first inlet 210. Accordingly, the light-emitting elements ED injected into the first inlet 210 may be readily injected into the micro channel 280 without being settled or aggregated.

In the micro channel 280, the Reynolds number of the fluid may range from about 1 to about 100.

The Reynolds number may be expressed by the following equation:

$$R e = \frac{ρ VL}{μ}$$

Here, μ denotes the viscosity of the fluid, p denotes the density of the fluid, V denotes the velocity of the fluid, and L denotes the length of the micro channel.

With the Reynolds number of the fluid within the above range, the light-emitting elements ED may move non-linearly and irreversibly due to inertial force, so that normal light-emitting elements EDN may be separated from abnormal light-emitting elements EDB. Herein, abnormal light-emitting elements EDB refer to ones that are relatively larger in size than normal light-emitting elements EDN. For example, abnormal light-emitting elements EDB may refer to longer ones or several ones that are not separated but stick together.

The way how normal light-emitting elements EDN and abnormal light-emitting elements EDB are separated from each other in the micro channel 280 will be described in more detail.

As shown in FIG. 16, the light-emitting elements ED may be aligned near the wall due to the viscoelastic fluid at the entrance of the micro channel 280. The light-emitting elements ED aligned near the wall move toward the center portion of the micro channel by wall-induced lift force Fₗᵢ. At this time, the wall-induced lift force may be proportional to the 6^{th} power of the particle size, and thus abnormal light-emitting elements EDB with a larger size reach the viscoelastic/Newtonian fluid interface earlier.

As shown in FIG. 17, as the light-emitting elements ED approach the viscoelastic/Newtonian fluid interface, an elastic lift force Fₑₗ due to the viscoelastic fluid may be generated. The normal light-emitting elements EDN may not pass through the viscoelastic/Newtonian fluid interface due to the elastic lift force Fₑₗ. For example, the abnormal light-emitting elements EDB may overcome the elastic lift force Fₑₗ as the wall-induced lift force Fₗᵢ acts more predominantly than the elastic lift force Fₑₗ and accordingly pass through the viscoelastic/Newtonian fluid interface.

As shown in FIG. 18, the abnormal light-emitting elements EDB passing through the viscoelastic/Newtonian fluid interface move toward the center portion of the micro channel by the elastic lift force Fₑₗ as the directions of the elastic lift force Fₑₗ and the wall-induced lift force Fₗᵢ are changed. For example, the abnormal light-emitting elements EDB may create an equilibrium position along with the shear gradient lift force and may move along the viscoelastic fluid. The normal light-emitting elements EDN staying in the Newtonian fluid may be spaced apart from the abnormal light-emitting elements EDB with moving in the direction of the viscoelastic fluid by forming a gap in the lateral displacement direction.

For example, the gap between the normal light-emitting elements EDN and the abnormal light-emitting elements EDB may be increased in the outlet flow path OFP, which is branched into the first outlet 330, the second outlet 340 and the third outlet 350, so that the normal light-emitting elements EDN may be separated from the abnormal light-emitting elements EDB.

For example, the normal light-emitting elements EDN and the Newtonian fluid may be discharged to the first outlet 330 through the first outlet path 300 and to the second outlet 340 through the second outlet path 310. The abnormal light-emitting elements EDB and the viscoelastic fluid may be discharged to the third outlet 350 through the third outlet path 320.

As described above, the particle separating apparatus 200 may separate abnormal light-emitting elements EDB from normal light-emitting elements EDN by using Newtonian fluid and viscoelastic fluid. For example, the particle separating apparatus 200 may eliminate settlement and aggregation of the light-emitting elements ED by disposing the vortex generator 400 at the inlet portion ILP.

With particle separating apparatuses 200, it is possible to separate a large amount of light-emitting elements ED at high speed.

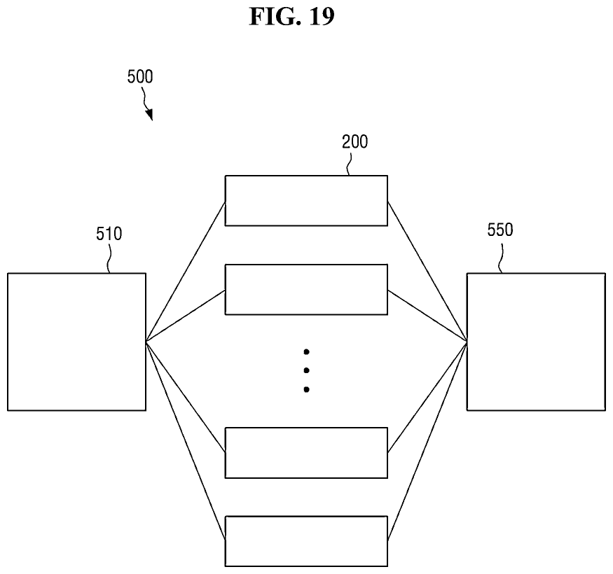

FIG. 19 is a schematic block diagram illustrating a large particle separating apparatus according to an embodiment.

Referring to FIG. 19, the large particle separating apparatus 500 may include an ink supply unit 510, particle separating apparatuses 200, and an ink retrieval unit 550.

The ink supply unit 510 may supply light-emitting elements and Newtonian fluid to the particle separating apparatuses 200. The ink supply unit 510 may store and supply a large amount of light-emitting elements ED and Newtonian fluid, like a large-sized water tank.

The particle separating apparatuses 200 may receive light-emitting elements ED and Newtonian fluid from the ink supply unit 510. The light-emitting elements ED and Newtonian fluid supplied from the ink supply unit 510 may be distributed to each particle separating apparatus 200, so that a large amount of light-emitting elements ED may be separated simultaneously.

The ink retrieval unit 550 may obtain Newtonian fluid including the separated normal light-emitting elements EDN from the particle separating apparatuses 200. The ink retrieval unit 550 may be connected to the particle separating apparatuses 200 and may store Newtonian fluid including a large amount of light-emitting elements.

While the invention is susceptible to various modifications and alternative forms, specific embodiments thereof are shown by way of example in the drawings and will herein be described in detail. It should be understood, however, that the drawings and detailed description thereto are not intended to limit the invention to the certain form disclosed, but on the contrary, the intention is to cover all modifications, equivalents, and alternatives falling within the spirit and scope of the invention as defined by the appended claims.

### Example: Fabrication of Particle Separating Apparatus of FIG. 8

The particle separating apparatus shown in FIG. 8 may be fabricated by using a polydimethylsiloxane (PDMS) mold. The width of the micro channel may be about 20 μm, the height may be about 50 μm and the length may be about 15 mm. The diamond of the first and second inlet paths may be about 30 μm, and the diamond of the third inlet path may be about 20 μm. The angle between the micro channel and the first outlet path and the angle between the micro channel and the second outlet path may be about 165°. The angle between the first outlet path and the third outlet path and the angle between the second outlet path and the third outlet path may be about 15°. The width of the first and second outlet paths may be about 50 μm, and the width of the third outlet path may be about 210 μm. A vortex generator 400 may be disposed under the first inlet.

### Embodiment 1

Particles may be mixed with water (e.g., a Newtonian fluid), and injected into the first inlet 210 at the flow rate of about 5 μl/min. The particles with diameters of about 2 μm and about 3 μm may be used, and 2×10⁷ particles may be mixed in water. A polyethylene oxide (PEO) solution with the molecular weight of about 600 kDa may be injected into the second inlet 220 as a viscoelastic fluid at the concentration of about 100 ppm, and particles may be separated by injecting it at the flow rate of about 20 μl/min.

### Embodiment 2

Particles may be separated under the same conditions as in Embodiment 1, except that the viscoelastic fluid may be injected at the flow rate of about 30 μl/min.

### Experimental Example

### Evaluation of Settlement and Separation of Particles

The separation of particles according to Embodiments 1 and 2 may be observed, and the settlement of particles according to whether the vortex generator 400 may be operated may be observed in Embodiment 1.

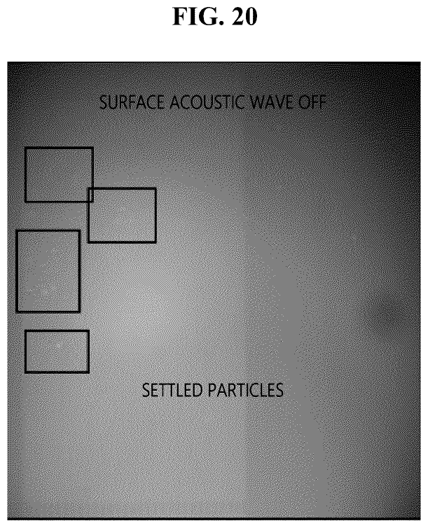

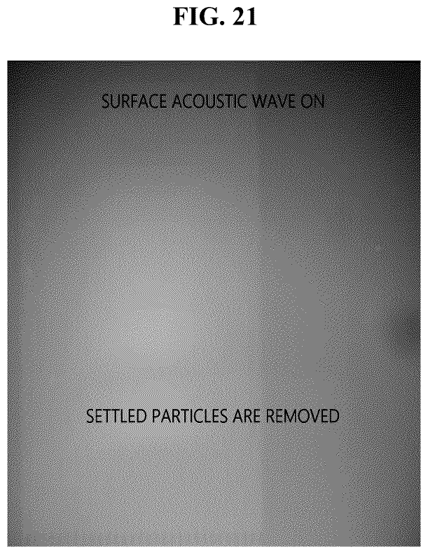

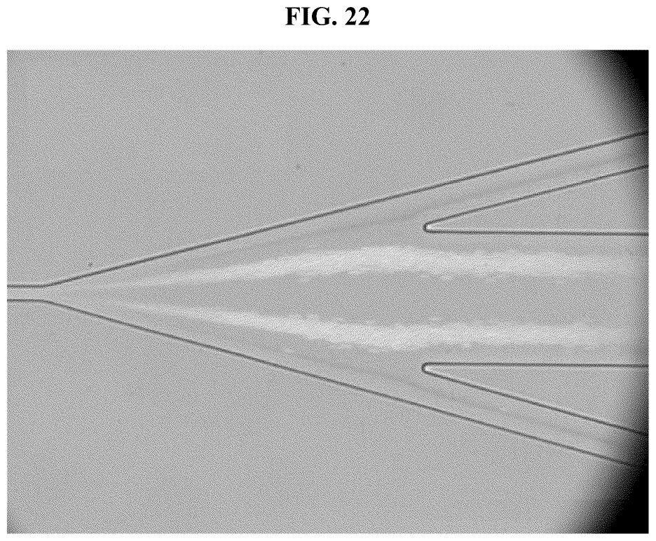

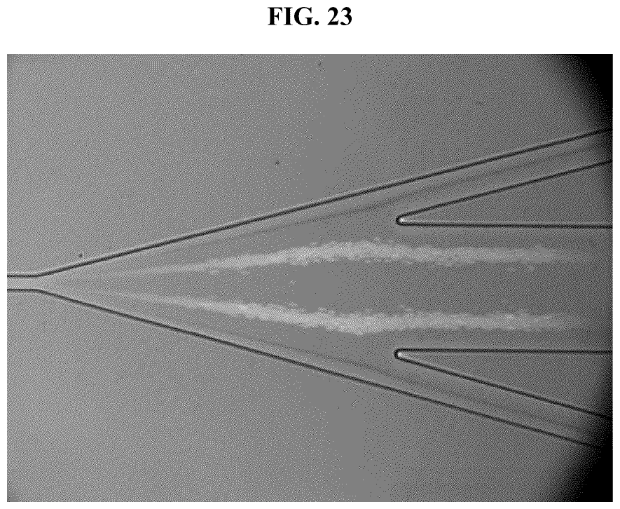

FIG. 20 is an image of the inlet portion of the particle separating apparatus 200 according to Embodiment 1 in case that the vortex generator 400 is not operated. FIG. 21 is an image of the inlet portion ILP of the particle separating apparatus 200 according to Embodiment 1 in case that the vortex generator 400 is operated. FIG. 22 is an image of the outlet flow path OPF of the particle separating apparatus 200 according to Embodiment 1. FIG. 23 is an image of the outlet flow path OPF of the particle separating apparatus 200 according to Embodiment 2. FIGS. 22 and 23 show accumulated images captured every second, where white ones are particles with the diameter of about 3 μm, and black ones are particles with the diameter of about 2 μm.

It is shown from FIGS. 20 and 21 that the particles may be settled at the lower side of the first inlet 210 of the inlet portion ILP in case that the vortex generator 400 may not be operated, but the particles settled at the lower side of the first inlet of the inlet portion ILP may be removed in case that the vortex generator 400 may be operated to generate surface acoustic waves.

Based on the results, it is shown that the particle separating apparatus equipped with the vortex generator 400 may prevent settlement and aggregation of the particles at the inlet portion ILP.

For example, it is shown from FIGS. 22 and 23 that larger particles with the diameter of about 3 μm may be separately moved to the third outlet path 320 in the outlet flow path OPF of the particle separating apparatus 200, while particles with the smaller diameter of about 2 μm may be moved to the first outlet path 300 and the second outlet path 310.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A particle separating apparatus comprising:
a base part;
a micro channel disposed in the base part;
an inlet portion disposed at an end portion of the micro channel, the inlet portion in which light-emitting elements, Newtonian fluid, and viscoelastic fluid are injected;
an inlet flow path connecting the inlet portion and the micro channel;
an outlet portion disposed at an opposite end portion of the micro channel, the outlet portion from which the light-emitting elements, the Newtonian fluid and the viscoelastic fluid are discharged;
an outlet flow path connecting the micro channel and the outlet portion; and
a vortex generator disposed under the inlet portion, the vortex generator that generates a surface acoustic wave.

2. The particle separating apparatus of claim 1, wherein the vortex generator comprises:
a piezoelectric substrate; and
first and second element electrodes disposed on the piezoelectric substrate and arranged alternately with each other in plan view.

3. The particle separating apparatus of claim 2, wherein an electrical signal applied to the first element electrode and the second element electrode is an alternating current (AC) electrical signal.

4. The particle separating apparatus of claim 1, wherein a frequency of the surface acoustic wave is in a range of about 10 MHz to about 300 MHz.

5. The particle separating apparatus of claim 1, wherein the micro channel has a ratio of height to width in a range of about 2 to about 3.

6. The particle separating apparatus of claim 5, wherein a width of the micro channel is in a range of about 20 μm to about 30 μm.

7. The particle separating apparatus of claim 1, wherein a length of the micro channel is in a range of about 15 mm to about 25 mm.

8. The particle separating apparatus of claim 1, wherein
the inlet portion comprises:
a first inlet through which the Newtonian fluid is injected, the Newtonian fluid in which the light-emitting elements are dispersed, and
a second inlet through which the viscoelastic fluid is injected, and
the vortex generator is disposed under the first inlet.

9. The particle separating apparatus of claim 8, wherein a ratio of a flow rate of the Newtonian fluid to a flow rate of the viscoelastic fluid is in a range of about 3 to about 7.

10. The particle separating apparatus of claim 9, wherein the flow rate of the Newtonian fluid is in a range of about 20 μl/min to about 30 μl/min.

11. The particle separating apparatus of claim 8, wherein
the inlet flow path comprises:
a first inlet path and a second inlet path connected to the first inlet, the first inlet path and the second inlet path through which the light-emitting elements and the Newtonian fluid move; and
a third inlet path connected to the second inlet path, the third inlet path through which the viscoelastic fluid moves, and
the first inlet path and the second inlet path surround the third inlet path.

12. The particle separating apparatus of claim 11, wherein a diameter of each of the first inlet path and the second inlet path is in a range of about 20 μm to about 40 μm.

13. The particle separating apparatus of claim 1, wherein
the outlet portion comprises:
a first outlet and a second outlet from which small light-emitting elements among the light-emitting elements and the Newtonian fluid are discharged; and
a third outlet from which large light-emitting elements among the light-emitting elements and the viscoelastic fluid are discharged, and
the first outlet, the second outlet and the third outlet are spaced apart from each other.

14. The particle separating apparatus of claim 13, wherein
the outlet flow path comprises:
a first outlet path connecting the micro channel and the first outlet;
a second outlet path connecting the micro channel and the second outlet; and
a third outlet path connecting the micro channel and the third outlet, and
the first outlet path, the second outlet path and the third outlet path are branched off from the opposite end portion of the micro channel.

15. The particle separating apparatus of claim 14, wherein an angle between the micro channel and the first outlet is in a range of about 150 degrees to about 165 degrees.

16. A method of separating light-emitting elements having different sizes, the method comprising:
providing a particle separating apparatus comprising:
a micro channel disposed in a base part;
an inlet portion disposed at an end portion of the micro channel, the inlet portion comprising:
a first inlet through which light-emitting elements and Newtonian fluid are injected, and
a second inlet through which viscoelastic fluid is injected;
an inlet flow path connecting the inlet portion and the micro channel;
an outlet portion disposed at an opposite end portion of the micro channel, the outlet portion from which the light-emitting elements, the Newtonian fluid, and the viscoelastic fluid are discharged;
an outlet flow path connecting the micro channel and the outlet portion; and
a vortex generator disposed under the inlet portion;
injecting the Newtonian fluid, in which the light-emitting elements are dispersed, into the micro channel through the first inlet, and injecting the viscoelastic fluid into the micro channel through the second inlet;
generating a surface acoustic wave by the vortex generator to propagate the surface acoustic wave to the first inlet;
separating normal light-emitting elements from abnormal light-emitting elements in the micro channel; and
discharging the normal light-emitting elements and the Newtonian fluid to the outlet portion through the outlet flow path, and discharging the abnormal light-emitting elements and the viscoelastic fluid separated from the normal light-emitting elements in the micro channel to the outlet portion through the outlet flow path.

17. The method of claim 16, wherein
the surface acoustic wave generates acoustic streaming that drives a flow of the Newtonian fluid moving in the first inlet, and
a vortex is generated in the Newtonian fluid by the acoustic streaming to disperse the light-emitting elements.

18. The method of claim 16, wherein
the outlet flow path comprises a first outlet path, a second outlet path and a third outlet path branched off from the micro channel, and
the outlet portion comprises a first outlet connected to the first outlet path, a second outlet connected to the second outlet path, and a third outlet connected to the third outlet path.

19. The method of claim 18, wherein
the normal light-emitting elements separated in the micro channel and the Newtonian fluid are discharged to the first outlet through first outlet path and the second outlet through the second outlet path, and
the abnormal light-emitting elements and the viscoelastic fluid are discharged to the third outlet through the third outlet path.

20. The method of claim 16, wherein the abnormal light-emitting elements among the light-emitting elements are larger in size than the normal light-emitting elements.
